(19) United States
(12) Patent Application Publication
(10) Pub. No.: US 2026/0214995 A1
(43) Pub. Date: Jul. 23, 2026

(54) A 3D SEMICONDUCTOR DEVICE AND STRUCTURE WITH HEAT SPREADER

(71) Applicant: Monolithic 3D Inc., Klamath Falls, OR (US)

(72) Inventors: Zvi Or-Bach, Haifa (IL); Jin-Woo Han, San Jose, CA (US); Brian Cronquist, Klamath Falls, OR (US)

(73) Assignee: Monolithic 3D Inc., Klamath Falls, OR (US)

(21) Appl. No.: 19/142,194

(22) PCT Filed: Sep. 21, 2022
(86) PCT No.: PCT/US2022/044165

§ 371 Date: Jun. 21, 2025

Related U.S. Application Data
(60) Provisional application No. 63/246,658, filed on Sep. 21, 2021.
(60) Provisional application No. 63/255,009, filed on Oct. 13, 2021.
(60) Provisional application No. 63/273,932, filed on Oct. 30, 2021.
(60) Provisional application No. 63/299,011, filed on Jan. 13, 2022.
(60) Provisional application No. 63/300,556, filed on Jan. 18, 2022.
(60) Provisional application No. 63/308,053, filed on Feb. 8, 2022.
(60) Provisional application No. 63/321,109, filed on Mar. 18, 2022.
(60) Provisional application No. 63/327,750, filed on Apr. 5, 2022.

(51) Int. Cl. H10D 88/00; H10W 20/43

(52) U.S. Cl. CPC H10D 88/00; H10W 20/43

(57) ABSTRACT

A 3D semiconductor device, the device including: a first level including logic circuits; a second level including a plurality of connectivity units, where the first level is overlaid by the second level, where each of the plurality of connectivity units includes at least one receiver circuit; and horizontally oriented transmission lines, where at least one of the plurality of connectivity units includes an Orthogonal Frequency Division Multiple Access (“OFDMA”) modulation circuit.

### BACKGROUND OF THE INVENTION

### 1. Field of the Invention

This application relates to the general field of Integrated Circuit (IC) devices and fabrication methods, and more particularly to multilayer or Three Dimensional Integrated Memory Circuit (3D-Memory) and Three Dimensional Integrated Logic Circuit (3D-Logic) devices and fabrication methods.

### 2. Discussion of Background Art

Over the past 40 years, there has been a dramatic increase in functionality and performance of Integrated Circuits (ICs). This has largely been due to the phenomenon of “scaling”; i.e., component sizes such as lateral and vertical dimensions within ICs have been reduced (“scaled”) with every successive generation of technology. There are two main classes of components in Complementary Metal Oxide Semiconductor (CMOS) ICs, namely transistors and wires. With “scaling”, transistor performance and density typically improve and this has contributed to the previously-mentioned increases in IC performance and functionality. However, wires (interconnects) that connect together transistors degrade in performance with “scaling”. The situation today is that wires dominate the performance, functionality and power consumption of ICs.

3D stacking of semiconductor devices or chips is one avenue to tackle the wire issues. By arranging transistors in 3 dimensions instead of 2 dimensions (as was the case in the 1990s), the transistors in ICs can be placed closer to each other. This reduces wire lengths and keeps wiring delay low and wire.

There are many techniques to construct 3D stacked integrated circuits or chips including:
Through-silicon via (TSV) technology: Multiple layers of dice are constructed separately. Following this, they can be bonded to each other and connected to each other with through-silicon vias (TSVs).
Monolithic 3D technology: With this approach, multiple layers of transistors and wires can be monolithically constructed. Some monolithic 3D and 3DIC approaches are described in U.S. Pat. Nos. 8,273,610, 8,298,875, 8,362,482, 8,378,715, 8,379,458, 8,450,804, 8,557,632, 8,574,929, 8,581,349, 8,642,416, 8,669,778, 8,674,470, 8,687,399, 8,742,476, 8,803,206, 8,836,073, 8,902,663, 8,994,404, 9,023,688, 9,029,173, 9,030,858, 9,117,749, 9,142,553, 9,219,005, 9,385,058, 9,406,670, 9,460,978, 9,509,313, 9,640,531, 9,691,760, 9,711,407, 9,721,927, 9,799,761, 9,871,034, 9,953,870, 9,953,994, 10,014,292, 10,014,318, 10,515,981, 10,892,016; and pending U.S. Patent Application Publications and applications, Ser. Nos. 14/642,724, 15/150,395, 15/173,686, 16/337,665, 16/558,304, 16/649,660, 16/836,659, 17/151,867, 62/651,722; 62/681,249, 62/713,345, 62/770,751, 62/952,222, 62/824,288, 63/075,067, 63/091,307, 63/115,000, 63/220,443, 2021/0242189, 2020/0013791, Ser. No. 16/558,304; and PCT Applications (and Publications): PCT/US2010/052093, PCT/US2011/042071 (WO2012/015550), PCT/US2016/52726 (WO2017053329), PCT/US2017/052359 (WO2018/071143), PCT/US2018/016759(WO2018144957 ), PCT/US2018/52332(WO2019/060798), and PCT/US2021/44110. The entire contents of the foregoing patents, publications, and applications are incorporated herein by reference.
Electro-Optics: There is also work done for integrated monolithic 3D including layers of different crystals, such as U.S. Pat. Nos. 8,283,215, 8,163,581, 8,753,913, 8,823,122, 9,197,804, 9,419,031, 9,941,319, 10,679,977, 10,943,934, 10,998,374, 11,063,071, and 11,133,344. The entire contents of the foregoing patents, publications, and applications are incorporated herein by reference.

In addition, the entire contents of U.S. patent application publication 2018/0350823 and U.S. patent applications 63/246,658, 62/963,166, 62/963,270, 62/983,559, 62/986,772, 63/108,433, 63/118,908, 63/123,464, 63/144,970, 63/151,664, 63/246,658, 63/255,009, and Ser. No. 17/151,867 are incorporated herein by reference.

Techniques to remove heat from 3D Integrated Circuits and Chips and protect sensitive metallization and circuit elements from either the heat of processing of the 3D layers or the operationally generated heat from an active circuit, will be beneficial.

Additionally the 3D technology according to some embodiments of the invention may enable some very innovative IC devices alternatives with reduced development costs, novel and simpler process flows, increased yield, and other illustrative benefits.

### SUMMARY

The invention relates to multilayer or Three Dimensional Integrated Circuit (3D IC) devices and fabrication methods. Important aspects of 3D IC are technologies that allow layer transfer. These technologies include technologies that support reuse of the donor wafer, and technologies that support fabrication of active devices on the transferred layer to be transferred with it. As well, use of heat protection materials and novel structures can allow higher operational temperatures, which can translate into faster performance of a 3D device.

In one aspect, a semiconductor device, said device comprising: a first level comprising a plurality of first transistors, wherein at least one of said plurality of first transistors comprises a single crystal channel; a first interconnect layer disposed on top of said plurality of first transistors; a plurality of ground lines disposed underneath said plurality of first transistors, said plurality of ground lines connecting from a ground to at least one of said plurality of first transistors; a plurality of power lines disposed underneath said plurality of first transistors, said plurality of power lines connecting from power to at least one of said plurality of first transistors; and a heat conductive material disposed so to be in contact with said plurality of ground lines and said plurality of power lines, wherein said heat conductive material comprises diamond molecules.

In another aspect, a semiconductor device, said device comprising: a first level comprising a plurality of first transistors, wherein at least one of said plurality of first transistors comprises a single crystal channel; a first interconnect layer disposed on top of said plurality of first transistors; a plurality of ground lines disposed underneath said plurality of first transistors, said plurality of ground lines connecting from a ground to at least one of said plurality of first transistors; a plurality of power lines disposed underneath said plurality of first transistors, said plurality of power lines connecting from power to at least one of said plurality of first transistors; a plurality of second transistors disposed underneath at least one of said plurality of first transistors, wherein said plurality of second transistors comprise diamond molecules, and wherein each of said plurality of second transistors comprise a connection to at least one of said plurality of power lines.

In another aspect, a 3D semiconductor device, the device comprising: a first level comprising logic circuits; a second level comprising a plurality of memory arrays, wherein said first level is overlaid by said second level, and wherein said first level comprises at least one Central Processor Unit (“CPU”) and at least one listed logic circuit: a Graphics Processor Unit (“GPU”), or a Tensor Processor Unit (“TPU”), or a Field Programmable Gate Array (“FPGA”).

In another aspect, a 3D semiconductor device, the device comprising: a first level comprising logic circuits; a second level comprising a plurality of memory arrays, wherein said first level is overlaid by said second level, wherein said plurality of memory arrays comprise a 3D non-volatile memory array, and wherein said 3D non-volatile memory array comprises neural network weight parameters.

In another aspect, a 3D semiconductor device, the device comprising: a first level comprising logic circuits; a second level comprising a plurality of memory arrays, wherein said first level is overlaid by said second level, and wherein said device comprises at least one Physical Unclonable Function (“PUF”).

In another aspect, a 3D semiconductor device, the device comprising: a 3D memory array, wherein said 3D memory array comprises a plurality of charge trap memory cells, wherein said plurality of charge trap memory cells comprise tunneling oxide thinner than 2 nm, wherein said plurality of charge trap memory cells comprise a back-bias, and wherein said back-bias is connected to a negative voltage to extend retention time of said charge trap memory cells.

In another aspect, a 3D semiconductor device, the device comprising: a first level comprising logic circuits; a second level comprising a plurality of connectivity units, wherein said first level is overlaid by said second level, wherein each of said plurality of connectivity units comprise at least one receiver circuit; and horizontally oriented transmission lines, wherein at least one of said horizontally oriented transmission lines is connected so to distribute a clock signal.

In another aspect, a 3D semiconductor device, the device comprising: a first level comprising logic circuits; a second level comprising a plurality of connectivity units, wherein said first level is overlaid by said second level, wherein each of said plurality of connectivity units comprise at least one receiver circuit; and horizontally oriented transmission lines, wherein at least one of said plurality of connectivity units comprises an Orthogonal Frequency Division Multiple Access (“OFDMA”) modulation circuit.

In another aspect, a 3D semiconductor device, the device comprising: a first level comprising logic circuits; a second level comprising a plurality of connectivity units, wherein said first level is overlaid by said second level, wherein each of said plurality of connectivity units comprises at least one receiver circuit; and horizontally oriented transmission lines, wherein at least two of said plurality of connectivity units share a same local oscillator.

And in another aspect, a 3D semiconductor device, the device comprising: a first level comprising logic circuits; a second level comprising a plurality of connectivity units, wherein said first level is overlaid by said second level, wherein each of said plurality of connectivity units comprise at least one transmitter circuit; and a plurality of horizontally oriented transmission lines, wherein at least two of said plurality of horizontally oriented transmission lines are selectively connected to a same transmitter circuit.

### BRIEF DESCRIPTION OF THE DRAWINGS

Various embodiments of the invention will be understood and appreciated more fully from at least the following detailed description, taken in conjunction with the drawings in which:

FIG. 1A illustrates an exemplary process step to integrate a diamond heat spreader in a 3D WSS;

FIG. 1B schematically illustrates an example of fluidic channels embedded in the diamond thermal spreader layer;

FIG. 1C is an exemplary drawing of a fluidic channel patterned on the CVD diamond layer, the channel covered by a cap having at least one inlet and one outlet for the cooling liquid/gas;

FIG. 1D is an exemplary drawing of a power distribution network of 3D WSS embedded in a thermally conductive but electrically non-conductive CVD diamond layer; and

FIG. 1E is an exemplary drawing of a power rail formed in/on the backside wafer surface of CVD diamond layer where in power rail is coupled to a power distribution network of a 3D WSS embedded in a thermally conductive but electrically non-conductive CVD diamond layer;

FIG. 2A is an exemplary drawing of a top portion of 3D WSS flipped and bonded into a temporary carrier wafer;

FIG. 2B is an exemplary drawing of another carrier substrate which may be blank silicon wafer and used to build a diamond heat spreader layer;

FIG. 2C is an exemplary drawing of the structure of FIG. 2B after depositing a diamond layer;

FIG. 2D is an exemplary drawing of the structure of FIG. 2C after depositing a metal layer and planarization;

FIG. 2E is an exemplary drawing of after bonding the structure of FIG. 2A with the power rails of the structure of FIG. 2D;

FIG. 2F is an exemplary drawing of the structure of FIG. 2E after removal of the base carrier;

FIG. 2G is an exemplary drawing of a back-side power supply option of the structure of FIG. 2F;

FIG. 2H is an exemplary drawing of a front-side power supply option of the structure of FIG. 2F;

FIG. 3A is similar to FIG. 16C of PCT/US21/44110, and is an exemplary drawing of adding a cooling level within the 3D system; and

FIG. 3B is an exemplary drawing of a repeating pattern of vias within the diamond level on top of the carrier wafer as a potential generic via pattern;

FIG. 3C is an exemplary drawing of a section of the 3D system similar the one referenced in FIG. 3A;

FIG. 3D is an exemplary table of instructions the 3D System could execute to operate and program at a high level as a large computing machine;

FIG. 3E is an exemplary drawing of the inclusion of the micro-code CC stored in location MM as part of exemplary 3D System controller instructions;

FIG. 3F is an exemplary drawing of consecutive operations of multiply and accumulation;

FIG. 3G is an exemplary drawing of the 3D System further adapted to better fit a DNN (Deep Neural Network) operation;

FIGS. 3H and 3I are exemplary drawings of the 3D System with one or more fabric switch wafers inserted between stacked wafers with various inter-wafer connection strategies;

FIG. 3J is an exemplary drawing of a fabric wafer of the 3D system with some exemplary switch strategies;

FIG. 4A is an exemplary schematic illustration of a multi-tiered PDN-DHS based on, but not limited to, the tree network;

FIG. 4B is an exemplary schematic illustration of an alternative arrangement to the structure/schematic of FIG. 4A where the global power rail is formed in DHS but the local power rail is formed in the back side of the 3D WSS;

FIG. 5A-5D are exemplary drawings of process steps and flow of multi-tiered PDN-DHS shown in FIG. 4A where the both local and global power rails are formed on CVD diamond wafer separately fabricated from 3D WSS wafer;

FIG. 6A-6D are exemplary drawings of process steps and flow to form multi-tiered PDN-DHS shown in FIG. 4B where the local power rail (LPR) is formed on the backside of the 3D WSS wafer but the global power rails (GPR) are formed on the CVD diamond wafer separately fabricated from the 3D WSS wafer;

FIG. 7A-7D are exemplary drawings of process steps and flow for a 3D WSS incorporating a diamond power gating transistor;

FIG. 8A is a reference chart of the theoretical limit of on-resistance as a function of breakdown voltage of various semiconducting materials;

FIG. 8B is a reference chart of the thermal conductivity of various materials;

FIG. 9A is an exemplary drawing of various components integrated on a DHS layer for a power step-down converter;

FIG. 9B is an exemplary drawing of global power rails which may be overlaid on a power gating DHS layer comprising the power step-down converters;

FIG. 10A-10D are exemplary drawings of power management functions and modules integrated with a 3D WSS wafer with unit blocks of 3D WSS; and

FIG. 11A-11B are exemplary drawings of a low RF-loss dielectric, such as, for example, silicon dioxide deposited during wafer fabrication or a glass wafer bonded, onto a 3D WSS wafer;

FIG. 11C is an exemplary drawing of a “physically unclonable function” (PUF) circuit;

FIG. 11D is an exemplary drawing of a bias condition to initialize a PUF leveraging the random effect of the oxide breakdown process;

FIG. 11E is an exemplary drawing of one type of a BTL structure;

FIG. 11F is an exemplary drawing of a 3D system's self-decision flow when a smart sensor module is included;

FIG. 11G is an exemplary drawing of a 3D system's self-decision and on-demand flows using a remote link;

FIG. 12A-12G are exemplary drawings of a process flow to form a 3D NOR memory structure having vertical S/D utilizing top and/or bottom gates;

FIG. 12H is an exemplary drawing of a transistor schematic in the ZY plane of a small slice of the 3D NOR structure of FIG. 12G;

FIG. 13A-13J are exemplary drawings of an alternative process flow to form a multilayer structure for which the final structure is similar to the 3D NOR structure illustrated in FIG. 12G;

FIG. 13K is an exemplary drawing of an enlarged 3D view of 4 memory cells of the 3D NOR structure illustrated in FIG. 13J;

FIG. 14A-14D are exemplary drawings of an alternative concept for integrating select transistors with a 3D NOR structure;

FIG. 15A-15D are exemplary drawings of additional alternative concepts at least wherein the select gate transistor could be a vertical channel transistor and be disposed in the 3D NOR or in the substrate;

FIG. 16A-16F are exemplary drawings of alternative structural arrangements which enable random selection of singular memory cells in a 3D NOR array without using any select transistors;

FIG. 17A-17C are exemplary drawings of a various 3D NOR-P multilayered memory stacks being modified to include a shared body contact;

FIG. 18A-18B are exemplary drawings of a technology CAD simulation of a body-contacted memory cell transistor vs a floating memory cell structure by plotting gate-voltage versus drain-current characteristics for logic ‘0’ and logic ‘1’ states;

FIG. 18C-18D are exemplary drawings of energy band diagrams in the source-channel-drain direction immediately after a programming operation in order to explain the mechanism of the ‘dead-time’;

FIG. 19A-19B are exemplary drawings of energy band diagrams and threshold voltage shift over data retention time, respectively, in order to explain the mechanism of retention time extension through back-gate bias;

FIG. 20A is an exemplary drawing of the memory cell transistor explaining the formation of a parasitic lateral bipolar device immediately after the programming operation;

FIG. 20B is a simulation result of bit-line transient current immediately after a programming operation for various body thicknesses;

FIG. 21A-21F are exemplary drawings of the process of forming metal-induced lateral recrystallization through at least one of source or drain;

FIG. 22 is an exemplary drawing of a 3D System alternative structure to the one presented in FIG. 16C of PCT/US21/44110;

FIG. 23 is an exemplary drawing of a connection switch and an signal amplifying element;

FIG. 24 is an exemplary drawing of an advanced connection which could be considered as a data switch;

FIG. 25 is an exemplary drawing of an X-Z cut view illustration of 3D system section having pairs of multiple pairs of X-Y connectivity levels;

FIG. 26 is an exemplary drawing of a schematic diagram of OFDMA circuits as presented in FIG. 3.10 of the Eren Unlu's Dissertation;

FIG. 27A is an exemplary drawing containing simple instruction overview of a communication control instruction module for a 3D System;

FIG. 27B is an exemplary drawing of instructions for a communication control instruction module designated to control the switch processors associated with the data transmission cycle;

FIG. 28 is an exemplary drawing of an X-Z cut view illustration of 3D system section similar to FIG. 25 with the addition of Parallel-Plate Waveguide (“PPW”); and

FIG. 29 is an exemplary drawing showing use of wireless connectivity from a 3D System to multiple other systems and back.

### DETAILED DESCRIPTION

An embodiment of the invention is now described with reference to the drawing figures. Persons of ordinary skill in the art will appreciate that the description and figures illustrate rather than limit the invention and that in general the figures are not drawn to scale for clarity of presentation. Such skilled persons will also realize that many more embodiments are possible by applying the inventive principles contained herein and that such embodiments fall within the scope of the invention which is not to be limited except by any appended claims.

Some drawing figures may describe process flows for building devices. The process flows, which may be a sequence of steps for building a device, may have many structures, numerals and labels that may be common between two or more adjacent steps. In such cases, some labels, numerals and structures used for a certain step's figure may have been described in the previous steps' figures.

Heat removal is a challenge for all Integrated Circuits (“IC”) these days. The higher number of active devices and the higher the rate of operation the higher amount of heat to removed. Of additional concern could be hot spots in which a high amount of heat is generated at a specific location. Such high heat can damage the device and/or reduce its reliability. Accordingly many heat management technologies has been developed over the years, including use of heat spreaders and heat removal such as by air or by the use of liquids. Among these is the use of diamond-based heat spreader(s) for a single device and now evolving into uses for 3D Wafer Scale Systems (“3D WSS”). One of the challenges of 3D WSS is power consumption. For example, a single 3D WSS may consume approximately 20 KW according to a survey in Reuther, Albert, et al., “Survey of machine learning accelerators.” 2020 IEEE High Performance Extreme Computing Conference (HPEC). IEEE, 2020, incorporated herein by the reference. Therefore, it is imperative to develop an efficient cooling strategy. A good thermal conductor placed in contact with such 3D WSS could remove heat rapidly away from undesired hot spot that decreases the performance and can cause failure.

Diamond offers an extraordinary thermal conductivity of more than 2,000 W/mK, which is 5× greater than many metals, for example, such as copper. The physical and thermal characteristics of diamond could be further found in at least Faili, Firooz, et al. “Physical and Thermal Characterization of CVD Diamond: A Bottoms-up Review.” 2017 16th IEEE Intersociety Conference on Thermal and Thermomechanical Phenomena in Electronic Systems (ITherm) IEEE, 2017., incorporated herein by the reference.

Diamond on silicon and diamond on oxide wafers has been often used for MEMS development. Such thin film or thick film diamond could be grown on those substrates by various methods such as Chemical Vapor Deposition (“CVD”), High-Pressure High-Temperature (“HPHT”) process from hydrocarbon gas mixture. More importantly, the diamond deposition process could be executed on large area substrates, for example, such as a 300 mm silicon substrate or a non-circular wafer, for example, comprising glass or ceramic or metal, or may be configured as a sheet for manufacturing efficiencies. Thus, the large-area diamond film could be grown and placed in contact with the 3D WSS.

An effective technique could be the use of a layer transfer such as is been presented in at least PCT/US21/44110, its entire contents incorporated herein by reference. The diamond layer could be grown on a carrier wafer and transferred on to the 3D WSS. Such could include back-grinding of the 3D WSS substrate and then transferring a diamond structure onto the back of the 3D WSS to provide effective heat spreading and heat removal.

The crystallographic phase of diamond referred in this invention could be controlled from amorphous to polycrystalline to single-crystalline. The diamond referred in the invention could also be a synthetic diamond, CVD diamond, or Diamond Like Carbon (“DLC”), interchangeably.

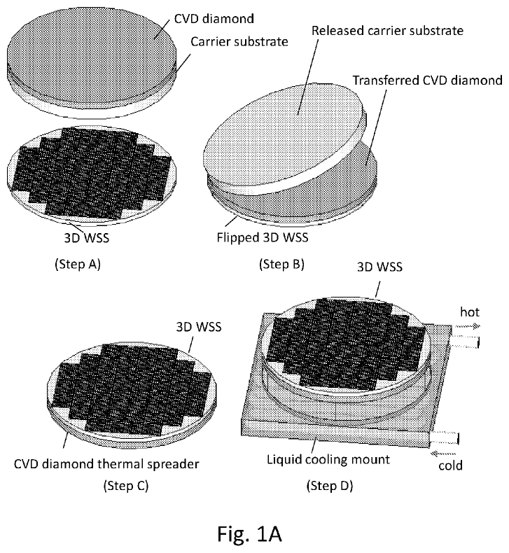

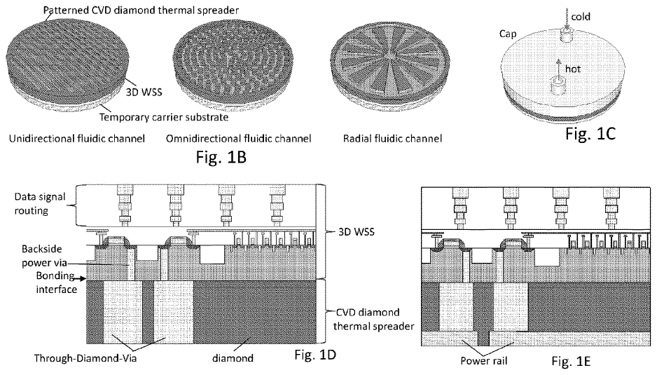

FIG. 1A illustrates an exemplary process step to integrate a diamond heat spreader in a 3D WSS. While the exemplary drawing uses a 300 mm full wafer, it should be understood that variations could be extended into a large sized chip such as the chip area greater than a single lithography reticle size, rectangular shaped chip, 2.5D system in package on interposer, or panel level system in packaged chip. In step A, a 3D WSS wafer and a CVD diamond wafer are independently prepared. The CVD diamond layer is grown on a carrier substrate. The carrier substrate could be, for example, comprised of such materials silicon, glass, ceramic, or metal, singly or in combination. After a CVD diamond layer is deposited, a coarse grinding and/or fine polishing step follows in order to planarize its surface. Examples of planarization processing of CVD diamond could be found in at least Roy, S., et al. “A comprehensive study of mechanical and chemo-mechanical polishing of CVD diamond.” Materials Today: Proceedings 5.3 (2018): 9846-9854; and in Yuan, Zewei, et al. “Chemical mechanical polishing slurries for chemically vapor-deposited diamond films.” Journal of manufacturing science and engineering 135.4 (2013). For this phase the process temperature could be much higher than 400° C. as no active device or metal are included in the structure.

Many of the levels of the 3D System could utilize glass substrate instead of single crystal silicon, Especially level that are not design for transistor formation such as levels for cooling or transmission lines.

As illustrated in step B, the CVD diamond wafer is flipped and bonded onto the backside of 3D WSS. Such bonding could use oxide to oxide bonding in which a thin layer of oxide is first deposited or grown on the proper surface such as the backside of the 3D WSS and on the top surface of the diamond wafer. This may be performed simultaneously or separately. After bonding, the carrier substrate is selectively removed or etched away, leaving the CVD diamond layer placed in contact with the 3D WSS. Diamond wafer bonding and removal of a carrier substrate could be found in at least Yushin, G. N., et al. “Study of fusion bonding of diamond to silicon for silicon-on-diamond technology.” Applied physics letters 81.17 (2002): 3275-3277; and Rabarot, M., et al. “Silicon-On-Diamond layer integration by wafer bonding technology.” Diamond and related materials 19.7-9 (2010): 796-805, the entire contents of all of the forgoing are incorporated herein by the reference.

In step C, the 3D WSS with a diamond heat spreader layer on its backside is shown. Depending on the system integration strategy, various cooling methods could be added. For example, a passive heat sink based on a metal pin- or fin-stack or heat sink-fan could be attached for air cooling. Or, ‘one’ or more heat pipes which contain a fluid or gas could be further added in the system. In another optional embodiment, as shown in Step D, an active liquid fluidic cooling mount could be used for heat removal of the 3D WSS.

Another embodiment of a diamond thermal spreader layer could include one or more fluidic or gas channels embedded in the diamond thermal spread layer for liquid cooling. FIG. 1B schematically illustrates an example of fluidic channels embedded in the diamond thermal spreader layer. FIG. 1B is the schematic illustration of the backside of at least one 3D WSS stacked on a CVD diamond thermal spreader layer shown in Step C of FIG. 1A. The front side of the 3D WSS on CVD diamond layer sub-structure is bonded to a temporary carrier substrate, at least for structural support during the subsequent processing. The backside surface of the diamond layer is patterned and trench etched to form a micro-fluidic channel.

The design of micro-fluidic channel could be varied. A first example is unidirectional fluidic channel where the cooling liquid confined in a directional channel and flows from the one end to the opposite end. A second example is an Omni-directional fluidic channel. The cooling liquid could freely flow in any directions according to the pressure and temperature gradients. A third example is a radial fluidic channel where the cooling liquid could flow from the center toward the boundary of the wafer or vice versa. The embedded fluidic channel could be patterned on the CVD diamond layer. The temporary carrier substrate could be removed and the 3D WSS could be mounted on a board, socket, or specially designed mount according to engineering, manufacturing, and financial considerations of the system integration (not drawn here). The fluidic channel patterned on the CVD diamond layer, the channel could be covered by a cap having at least one inlet and one outlet for the cooling liquid/gas as is illustrated in FIG. 1C.

In some cases it might be desired to punch holes through the 3D System wafer stack. Such holes could be used to provide mechanical support to hold the mechanical fixture holding the 3D System and support to the base and the cover of the mechanical holding fixtures. Such holes are being used with Cerebras' Wafer-Scale Engine (WSE). Such holes could be formed incrementally as the 3D System are being formed, or as a late step using deep etch process like plasma etching. Such holes could also be used as part of the 3D System cooling.

FIG. 1D shows another embodiment which is related to a power distribution network of 3D WSS embedded in a thermally conductive but electrically non-conductive CVD diamond layer. The power distribution system could be formed in the CVD diamond layer and feed power into the 3D WSS from its backside while the front side is used for the data routing. This could be reversed. For the back-side power delivery system, the 3D WSS could have a backside power via or embedded power rail, as illustrated in at least U.S. patent application publication 2020/0105759 A1, the entire contents of the forgoing reference is incorporated herein by the reference.

The backside wafer level processing may continue in any method known to process the front-side wafer. The backside power supply to 3D WSS may be attained through a Through-Diamond-Via (“TDV”) formed in the CVD diamond thermal spreader layer. At least two TDVs corresponding to ground (Vss) and power (Vdd), respectively, could be formed per unit, a unit being for example, such as a block or a die of 3D WSS. The formation of a power bus could be processed after transferring a CVD diamond layer on to the backside of a processed 3D WSS.

Various designs of power delivery could be obtained. For example, as illustrated in FIG. 1E, power rail is formed in the backside surface of CVD diamond layer. While the TDV(s) deliver power vertically, the power rail(s) could deliver the power horizontally. Use of diamond makes the heat removal using the power delivery network easier as the diamond layer is unique by provide electrical isolation while also providing excellent thermal conductivity. The power delivery network provides a good thermal conductivity to almost all of the 3D WSS transistors and being able to connect both the Vss lines and the Vdd lines without concern of shorts to the heat-spreader-the diamond layer-greatly simplifies the heat removal structure.

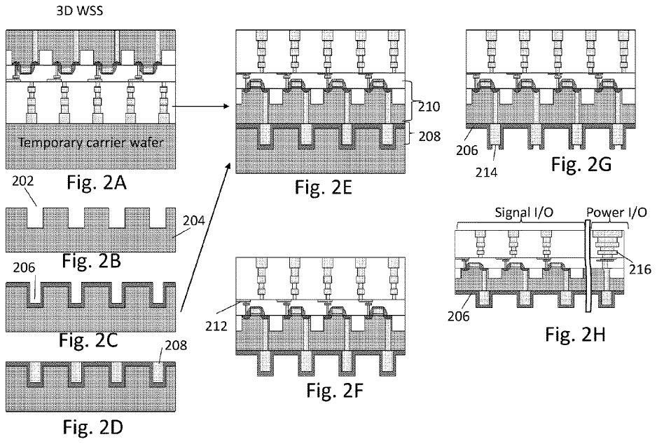

In FIGS. 1 and 2, the fluidic channel or TDV is formed on the backside of CVD diamond layer after transferring CVD diamond layer on 3D WSS. Alternatively, the fluidic channel or TDV could be formed the CVD layer diamond layer on the temporary carrier wafer before the wafer bonding and layer transfer. Then, a necessary post processing such as metal pad opening or fluid inlet/outlet opening could follow.

Addition alternative is to form the diamond layer on non flat surface. In this alternative, the fin-shaped diamond surface is patterned on a temporary carrier wafer separately from 3D WSS wafer. FIG. 2A illustrates a top portion of 3D WSS flipped and bonded into a temporary carrier wafer. FIG. 2B illustrates another carrier substrate 204 which could be blank silicon wafer and used to build a diamond heat spreader layer. Trenches 202 could be formed in the substrate 204 using lithography and etching. The trenches depth could be below 1 micron or below 10 microns or even tens of microns. These trenches could be used to form the back side power rails as is presented in the following. The trenches width could be below 1 micron or below 10 microns or even tens of microns. The trenches length could be the size of a unit die reticle or up to full wafer length.

FIG. 2C illustrates the structure after depositing diamond layer 206. The diamond layer thickness could be below 1 micron or below 10 microns or even tens of microns.

FIG. 2D illustrates the structure after depositing metal layer 208 and planarization of the surface using such as CMP, thus leaving metal rails within the trenches. The power rails could serve plurality of power lines such as Vdd, Vss and so forth. The diamond layer provides unique advantage as it provide excellent heat conductivity while also provide excellent electrical isolation. Accordinglly the various power rail could have good contact with the diamond layer to provide good thermal conductivity while high electrical isolation to remove risk of power line shorts.

FIG. 2E illustrates after bonding the structure with the power rails 208 at the back of a target wafer such as the 3D WSS having back side power connection 210 similar to what was presented in FIG. 1D-1E. The bonding could be hybrid bonding which include metal to metal and oxide to oxide bonding or just metal to metal bonding.

Then, the temporary carrier wafer of 3D WSS could be removed.

FIG. 2F illustrates the structure after removal of the base carrier 204 which could be done by grinding and etching leveraging the etch selectivity of the diamond layer 206.

Such flow provides heat spreader diamond layer with extended surface 212 contact with the power rails at the top and extended surface contact with the heat removal at the bottom for better overall heat removal.

While the data routing pad could be formed the front surface of 3D WSS, the pad for the power supply could be formed either front side or back side of 3D WSS. FIG. 2G illustrates an example of back side power supply. For the back side power supply, a portion of diamond layer 206 could be patterned 214 to allow connection to the power metal 208.

An additional embodiment, FIG. 2H, illustrates an example of a front side power supply. For a front side power supply, a diamond layer 206 may fully encapsulate and protect the power metal layer. Instead, some portion of front side metallization region could be assigned for the power supply. This front side power supply 216 could be formed along the circumference near the edge region of 3D WSS.

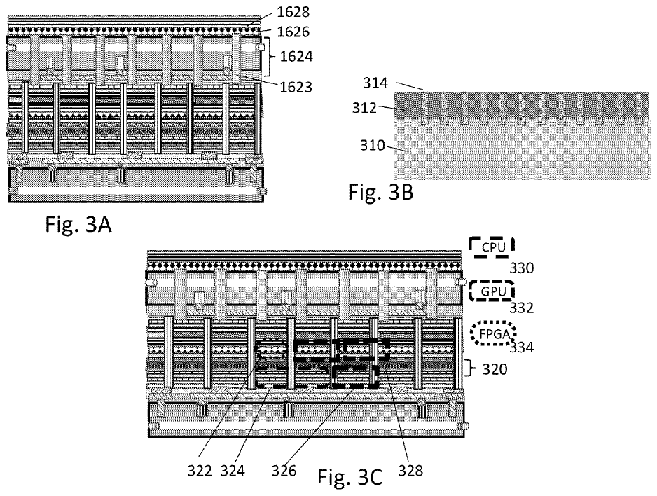

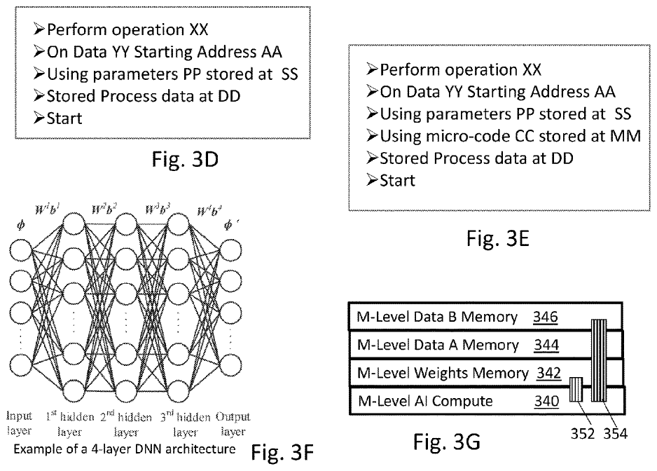

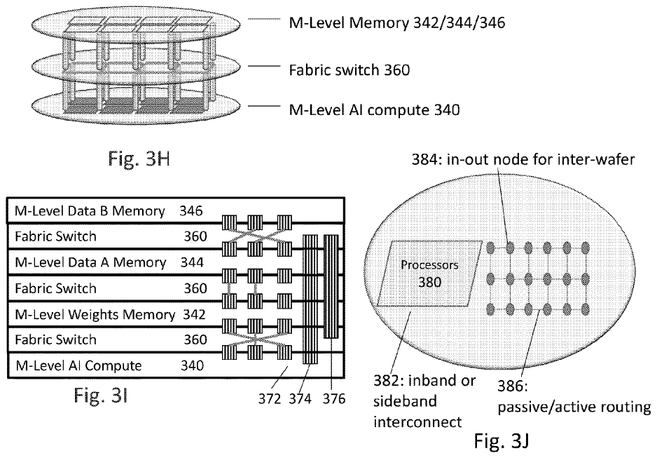

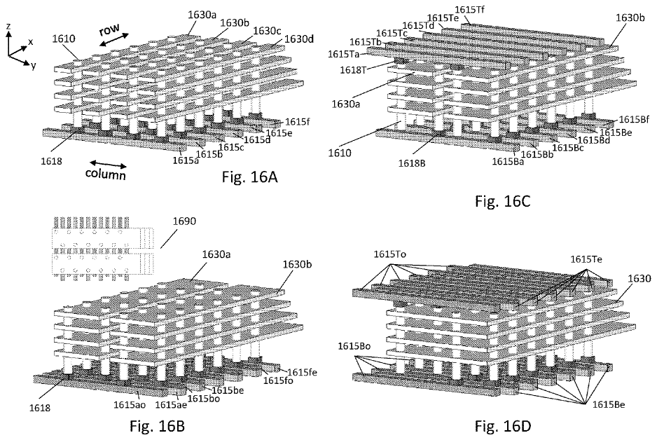

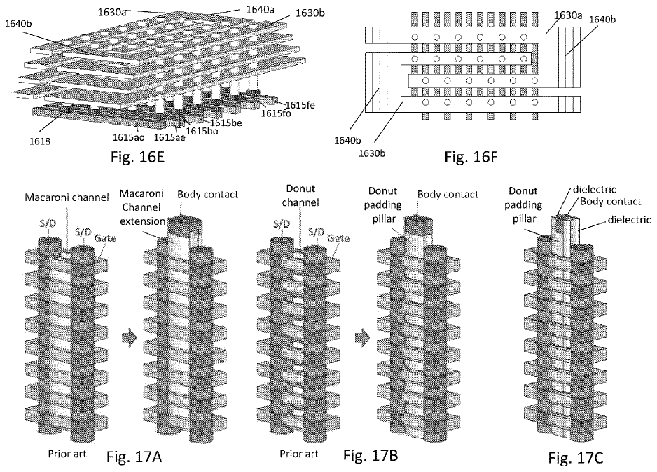

FIG. 3A is similar to FIG. 16C of PCT/US21/44110, incorporated herein by reference. It illustrates adding a cooling level 1624 within the 3D system. Such cooling level could include diamond layer using similar techniques to those presented herein. Such in-between levels diamond layer may need Through Diamond Via (“TDV”) similar to 1623. These vias could be formed by etching and filling after the diamond layer has been transfer or at the diamond level before transferring into the 3D system.

The 3D system, such as been illustrated in FIG. 3A and related art allow heterogeneous integration of logic memory and interconnect technology such as RF or optical interconnect. It may include large scale integration in the horizontal diction such as reticle size multi reticle size or even wafer level. The memory levels could include mix of memory technologies such as high speed memories such as DRAM and high density memories such as 3D NAND. The system could include multiple levels of logic and could include memory level in-between logic level with dual access of the memory from logic below and logic above. The system could be constructed with array of units which could be with different sizes. 3D system could be architected to solve high intensity compute challenge such as AI (Artificial Intelligent) training. The logic level could be architect as heterogynous logic including technologies such as CPU, GPU, TPU, FPGA, ASIC or others. Even those could be heterogynous such as 8 bit CPU, 64 bit CPU, RISC type CPU and CISC CPU. And so the other form of logic computing architecture like floating point GPU or fixes point GPU, large array of cores GPU and moderate size of cores array GPU and so forth. A smart system controller can manage a compute challenge such query and brake it up and allocate tasks to a proper logic resources. These tasks could be process in serial or even in parallel to achieve completing the task in a better way considering execution time and power. Alternatively, the break up could be done remotely and load in together with the query.

For many AI processes such as deep learning massive amount of data need to be multiplied by a large set of weights which could be described as matrix multiplication and logic such as TPU or GPU is commonly used for such computation. The logic fabric of such a 3D System may include a large number of logic multiplier circuits or circuits that do logic multiplication and accumulation. These multiplier circuits could be part of the TPU or GPU circuits and could be part of other logic circuits. Other type of processes could include preprocessing of the data set and could include non-linear adjustments for which CPU type logic could be preferred. FIG. 3C illustrates a section of the 3D system similar the one referenced in FIG. 3A. It illustrates having CPU 330, GPU 332 and FPGA 334 type resources, as part of the 3D System logic levels. So for example a logic area 324 implementing CPU could be used to process some data set in the memory 320 and store it back to an assign location in the memory space. Then the system controller activates GPU 326 and/or GPU 328 to process the data such as performing matrix multiplication. And then the system controller can activate an FPGA 322 type logic having programmable logic to perform finishing computation for the data to be ready to be delivered as a response to the Query. Integrating multiple type of logic structure within the 3D System could allow tailoring the system for a specific task. Sharing a large memory space within the 3D system could help reducing the overall power and reduce data movement's power, for efficient processing.

Such a 3D System could have a pre-set instruction set for each of its ‘processing elements’ such as CPU, GPU, FPGA. And the 3D System control could operate and program at the high level as large computing machine using instructions as is illustrated in FIG. 3D. It could instruct a ‘processing element’ to perform a specific operation XX such as multiple the data YY stored at location AA by the set of weights PP stored at SS, and store the results in DD.

The main 3D System controller could compile and construct the operating program to respond to a specific Query by a built-in compiler or that the compilation could be done externally and provided to the 3D System controller together with the Query.

The activation of the various computing resources within the 3D System could include providing the micro-code or a portion of the micro-code to that resource prior to activating its operation. Such micro-code could be in the form of a bit-stream for an FPGA resource or a machine language code for CPU type resources and so forth. FIG. 3E illustrates the inclusion of the micro-code CC stored in location MM as part of the 3D System controller instructions. And as stated before it could be pre-stored in the 3D System or loaded in as part of initiation of the system to a specific data processing task or Query operation task.

Artificial Intelligence (AI) and more specifically Deep Neural Network (“DNN”) are becoming a very important application for computing resources and expected to become even more important in the future. In many cases a massive amount of data is being processed with these types of computing algorithms which require a massive amount of matrix multiplication which results in consecutive operations of multiply and accumulation as illustrated in FIG. 3F. FIG. 3F is copied from a paper by Xiang, Houhong, et al., “A novel phase enhancement method for low-angle estimation based on supervised DNN learning.” IEEE Access 7 (2019): 82329-82336, incorporated herein by reference.

The presented 3D System herein could be further adapted to better fit such a DNN operation, as is illustrated in FIG. 3G, by dedicating a memory level 342 to hold the weights, additional memory level 344 to hold the data to be multiplied, and additional memory level 346 to hold the results. As often is common and is illustrated in FIG. 3F, the result of one step becomes the input for the following step. Accordingly the Data A and Data B could act one time as the input storage and the other time as the results storage.

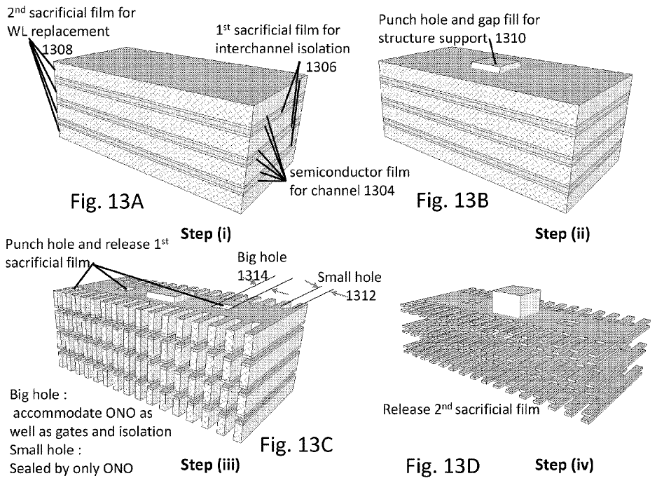

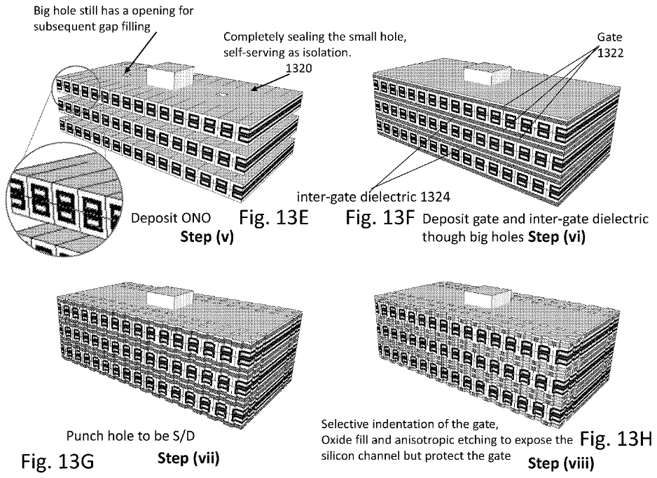

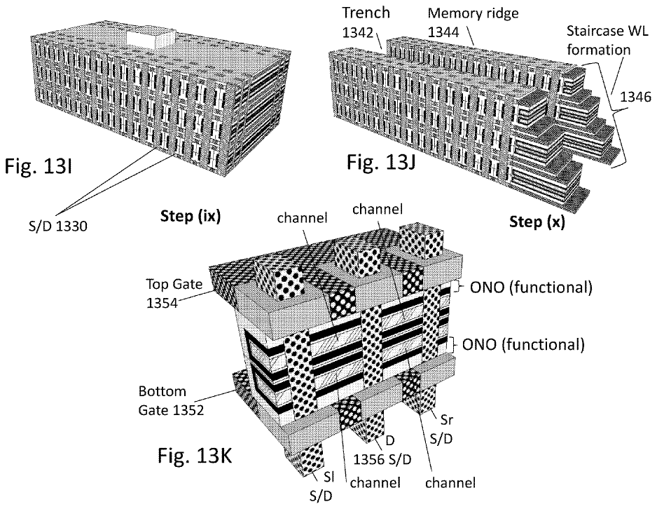

PCT application PCT/US21/44110, incorporated herein by reference in its entirety, describes the formation of such a 3D System which could include stacking levels which are called M-Levels, and is illustrated in reference to its FIG. 13A. Such an M-Level includes the memory control and the memory storage. As presented in PCT/US21/44110 one or more vertical bus per unit could be used to support data transfer between levels within the 3D System. For a DNN application it could be advantageous to use a vertical bus 352 for the weights data and additional one or more vertical bus 354 for the data in and data out transfer. Construction of the 3D System to support a DNN application is appropriate as these applications are very demanding for computing resources due to the very large amount of data that needs to be transferred in and out.

In computing high density memory such as 3D NAND is commonly used as storage while for high speed memory such as DRAM is used for cache memory. For DNN applications, in which the streaming of data to the compute engine is sequential as large matrices are being multiplied, a smart controller could be used to read in parallel a full row of the matrix and then, using an internal buffer, transfer serially the data to be multiplied by the logic level 340. The results could then be transferred serially to a smart storage controller to write/program in parallel to the storage location. Accordingly, a smart memory controller could allow use of high density memory even to relatively high speed operation leveraging the knowledge of the data structure, and the sequential operation nature of DNN application.

In general, SW applications require different compute and memory resources. For example, HPC workloads require many compute resources, but big-data applications require high-capacity memory with a small amount of compute resources. In addition, the DNN network shown in FIG. 3F has different number of layers, different nodes per each layer and interconnect configuration according to the DNN models. Therefore, in a 3D WSS, it could be advantageous to allocate resources flexibly according to the application's requirements on compute and memory resources.

In a 3D WSS, a functional wafer (i.e., GPU, AI, memory) could include multiple identical units which can provide specific computational capability or memory capacity. Under the given workload, the required number of units could be grouped from the various functional wafers, and connected together across wafers to construct the task allocated sub-system configuration. For example, a large number of GPUs resources with a small capacity memory could be configured to be connected to support the desired applications. On the other hand, for another application, a small number of GPUs could be configured to be connected to a large capacity of memory such as for big-data applications.

In order to efficiently configure HW resource groups according to the application's requirement and to support data movement between stacked wafers, one or more fabric switch wafers 360 could be inserted between stacked wafers as shown in FIG. 3H and FIG. 3I. The functional wafer could be connected to the adjacent the fabric wafer using TSV 372, or it can jump to the fabric switch through TSV 374. TSV 376 could connect two or more fabric switch wafers directly.

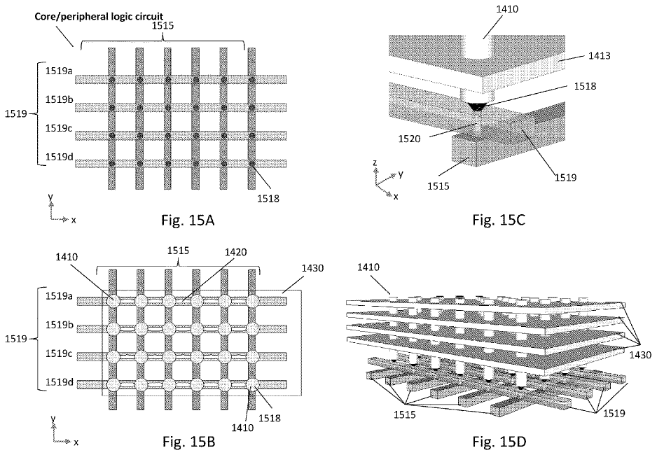

The fabric wafer shown in FIG. 3J may include in-out node 384, which is connected to the TSV 372/374/376, interconnect lines 386, optional management processor 380 to configure routing and priority, optional inband or sideband interconnect 382 to program the management processor. The interconnect line 386 can be passive routing layers to connect two nodes, or it can include active devices also to re-drive signals. The node 384 transfers incoming data to the destination based on destination address (packet switching) or based on a pre-configured port by the management processor (circuit switching). The network topology is not limited to a mesh network depicted in FIG. 3J. It can be configured as, for example, mux, crossbar, torus, Clos, fat tree, ring interconnect, and multiple ring interconnect according to the traffic flow. The fabric switch wafer can include a processor to change interconnect configuration and routings. The user can change interconnect configuration and routing by accessing the processor in the fabric switch wafer through an in-band or sideband protocol. In addition, the SW can set priority per each requestor to allocate more bandwidth to the application. The X-Y interconnect could utilize a switch such switch fabric 360 or passive/active routing 386 or utilize the electromagnetic interconnect fabric as presented in PCT application US21/44110, incorporated herein by reference, such as in reference to its FIG. 15F-15O.

One additional element in which electromagnetic waves could be utilized is in the distribution of a global clock signal. In general, a 3D system can be structured into many independent units, and, further, each unit could use its own internal clock and communicate with other units by utilizing packet communication with asynchronous communication channel(s) disposed in-between units. These units could also be grouped. This communication or a portion of it could be accomplished with electromagnetic waves. Alternatively, a group of units could share a global clock and communicate with synchronous channel(s). Common clock tree technology using an electromagnetic wave or waves for the global clock could reduce the overall power dissipation of such clock distribution structures. One option for including electromagnetic technology is the use of surface waves-SWI as presented as a one-to-many communication technology in at least ref # 1579 of FIG. 15G of PCT application US21/44110, incorporated herein by reference. Alternatively, an optical wave distribution of the global clock could also be used.

The fabric switch wafer can be used to isolate or un-map faulty unit/die in the functional wafer. For example, un-repairable DRAM unit locations within the DRAM wafer may be recorded during wafer-test, and this information is delivered to the management processor in the fabric switch wafer. The management processor then won't map these bad/faulty DRAM units to any computational resource. The same processes can be applied to the GPU/AI wafers also.

Additional option is to form a repeating pattern, as is illustrated in FIG. 3B, of via 314 within the diamond level 312 on top of the carrier wafer 310 as a generic via patterns. Such generic structure of diamond heat spreader could be used for various 3D Systems. Such approach is leveraging the diamond layer electrical isolation aspect.

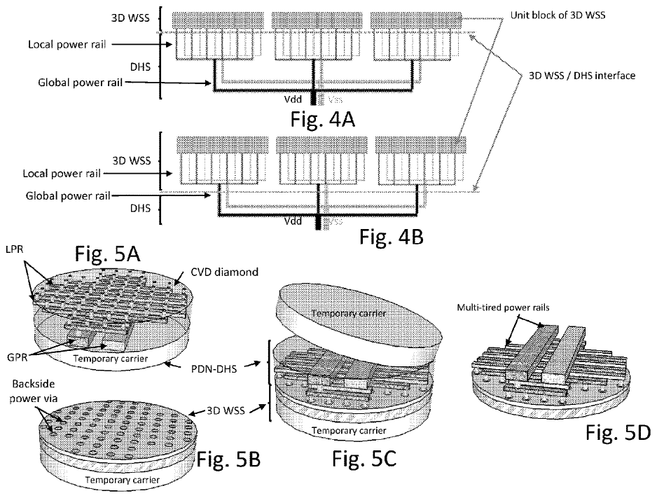

In another alternative, a power distribution could be formed as a multi-tiered network. A type of power distribution could be radial, loop, tree, or their combinational network where the Power Distribution Network (“PDN”) is at least a part of network is included in the Diamond Heat Spreader (“DHS”). Hereinafter, the diamond heater spreader embedding power distribution network (DPN) in part or in full is referred to PDN-DHS. FIG. 4A-B schematically illustrate the multi-tiered PDN-DHS based on, but not limited to, the tree network. The multi-tiered PDN-DHS includes at least two supply voltages such as Vdd and Vss. However, a PDN-DHS with multiple supply voltages (such as Vdd1, Vdd2, Vdd3, Vss1, Vss2, Vss3 and so on) externally supplied could be formed following the same concept. The multi-tiered PDN-DHS forms at least two-tiered power rails such as global power rail and local power rail. The global power rail connects external power supply to its children power rail such as local power rail. The local power rail connects its parent's power rail into unit block of 3D WSS, where unit block of 3D WSS could be a die, compute core, any other functional block also referred in the incorporated by art reference as “unit”. If necessary, at least one or more intermediate power rail could be added between the global and local power rail. The global power rails deliver power in longer haul and accommodate higher current level so that the voltage drop, fluctuation, and ground bounce, could be minimized. In one embodiment of PDN-DHS, both local and global power rails are formed in DHS as shown in FIG. 4A. Alternatively, the global power rail is formed in DHS but the local power rail is formed in the back side of the 3D WSS as illustrated in FIG. 4B. The local power rail could be formed along the back side power via of 3D WSS during the back side wafer process step of 3D WSS. It could be noted again that a unique advantage of diamond material for heat spreading and heat removal is very good heat conductivity while have extremely low electrical conductivity or extremely high breakdown voltage. Accordingly forming PDN-DHS could be relatively simple as there is no concern for shorting Vdd and Vss while providing excellent thermal path for heat from the power rails to the diamond as part of the heat removal path.

FIG. 5A-5D illustrates an exemplary process step of multi-tiered PDN-DHS shown in FIG. 4A where the both local and global power rails are formed on CVD diamond wafer separately fabricated from 3D WSS wafer. FIG. 5A illustrates the multi-tiered metallization structure such as tree-structure been formed in CVD diamond. Such multilevel metallization process is a repeated processes of adding CVD diamond layer, CMP processing the diamond, making hole by lithography and etching, adding a metal, and CMP processing the metal. In order to reduce the voltage fluctuation, a hierarchical routing of power lines, larger metal line in the lower level such as Global Power Rail (“GPR”) and smaller metal line in the upper level such as local power rail (LPR) are layered as a tree structure embedded in the CVD diamond dielectric. The size and the density of power line are progressively decreased and increased, respectively, as the power line layer gets closer to the transistor layer or the backside power via of 3D WSS. The LPR is connected to the GPR by multiple via arrays. In this power network, Vss and Vdd lines are paired and such pair of Vdd and Vss lines are repeated. If required, some other control signal other than power could be added. FIG. 5B illustrates the backside of 3D WSS after completing the backside power via process. FIG. 5C illustrates flipping PDN-DHS wafer shown in FIG. 5A and bonding onto the backside of 3D WSS wafer shown in FIG. 5B, followed by the removal of temporary carrier substrate of the PDN-DHS. FIG. 5D shows the 3D WSS with PDN-DHS after removing the temporary carrier substate. For better view of power rails, CVD diamond layer is not shown.

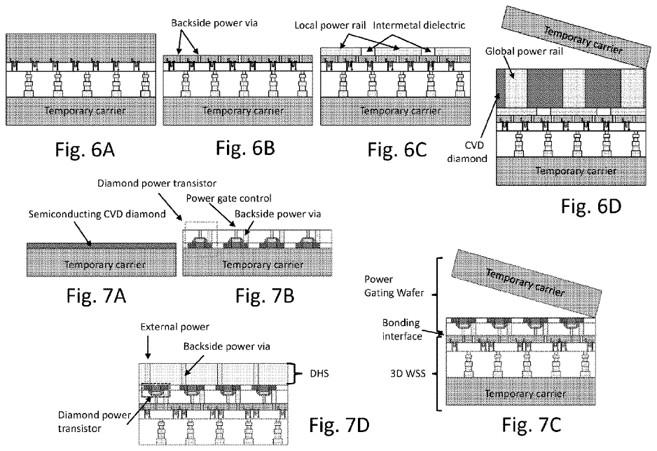

FIG. 6A-6D illustrates an exemplary process step of multi-tiered PDN-DHS shown in FIG. 4B where the Local Power Rail (“LPR”) is formed on the backside of 3D WSS but the Global Power Rails (“GPR”) are formed on the CVD diamond wafer separately fabricated from 3D WSS wafer. FIG. 6A shows the flipped 3D WSS wafer mounted on a temporary carrier substrate. In FIG. 6B, the backside of 3D WSS wafer is grinded and polished back, followed by the backside power via formation process. In FIG. 6C, a local power rails are further processed on the backside power via. The local power via processed on the backside of 3D WSS could be isolated with intermetal dielectric, The intermetal dielectric for backside power rail could be a silicon dioxide or CVD diamond as well. The global power rail that is separated fabricated on a CVD diamond wafer according to a method previously explain inhere. The diamond heat spreader wafer is flip and bonded on the 3D WSS wafer, followed by removing the temporary carrier as shown in FIG. 6D.

In another alternative, diamond power transistors could be used as a power gating switch. The diamond is not only attractive as a heat spreader due to is exceptional thermal conductivity but also promising as a power transistor channel material due to its hole mobility, high critical electric field, and large bandgap. Therefore, the diamond power transistor is getting attention for ultra-high voltage and high temperature applications beyond silicon and other compound semiconductor-based power devices, as discussed in, Geis, Michael W., et al. “Progress toward diamond power field-effect transistors.” physica status solidi (a) 215.22 (2018): 1800681, Umezawa, Hitoshi. “Recent advances in diamond power semiconductor devices.” Materials Science in Semiconductor Processing 78 (2018): 147-156, Aleksov, A., et al. “Diamond field effect transistors—concepts and challenges.” Diamond and Related Materials 12.3-7 (2003): 391-398, Denisenko, A., and E. Kohn. “Diamond power devices. Concepts and limits.” Diamond and related materials 14.3-7 (2005): 491-498, all of which are incorporated herein by references. FIG. 7A-7D illustrates an exemplary process step for 3D WSS incorporating diamond power gating transistor. A thin layer of semiconducting CVD diamond is deposited on a temporary carrier substrate such as silicon as shown in FIG. 7A. An important aspect in this step is that the CVD diamond should be semiconducting type for transistor fabrication, by incorporating dopants, whereas those CVD diamonds used to be a dielectric phase when it is used as heat spreader. The diamond power transistor is fabricated on the semiconducting CVD diamond layer as shown in FIG. 7B. The device structure of the diamond power transistor could be, but not limited to, a planar single gate, FinFET, nanowire, nanoribbon, ring-gate, or any other types having at least source, drain, and gate regions. The diamond power transistor may further include a contact metal at least for the source or drain to serve as backside power via and a metal at the gate to play as a power gate control. This wafer is referred to power gating wafer. The power gating wafer is flip and bonded onto a 3D WSS on temporary carrier, followed by removing the temporary carrier portion from the power gating wafer as illustrated in FIG. 7C. As shown in FIG. 7D, the diamond heat spreader layer with backside power via or backside power rail or even backside multi-tiered power rails could be added using a method previously explained in here. The power signal could be connected from external power supply to the unit of 3D WSS via diamond power transistor, where the external power could be connected to the source of the diamond power transistor and the local supply of the power into the unit of 3D WSS could be connected to the drain of the diamond power transistor. The gate of the diamond power transistor could be controlled from the power gating signal from 3D WSS.

Some embodiments may also include at least one power step-down converter implemented on a DHS layer of the 3D WSS. The power step-down converter could be alternatively referred to as, for example, a voltage regulator, voltage converter, or power optimizer. The 3D WSS may adapt to and/or use a main supply voltage far greater than the various voltages necessary for the logic, memory, cache, or other functional blocks. For example, the main supply voltage could be about DC 12V or about DC 24 V or about DC 48 V, or any other voltages and such main supply voltage could be regulated by a power step-down converter to 5V, 3V, 1.2V or any other voltages needed by the logic, memory, cache, or any other functional blocks. The external supply voltage could be one value and the power step down converter may yield various voltages to feed various functional blocks. Such a concept could simplify the distribution of power throughout the 3D WSS by requiring a smaller current to deliver the same power and to isolate power ripple generated in one location due to an instant current needed in one zone from the power to other zones as each zone could have its own power supply formed from the higher supply voltage distribution network.

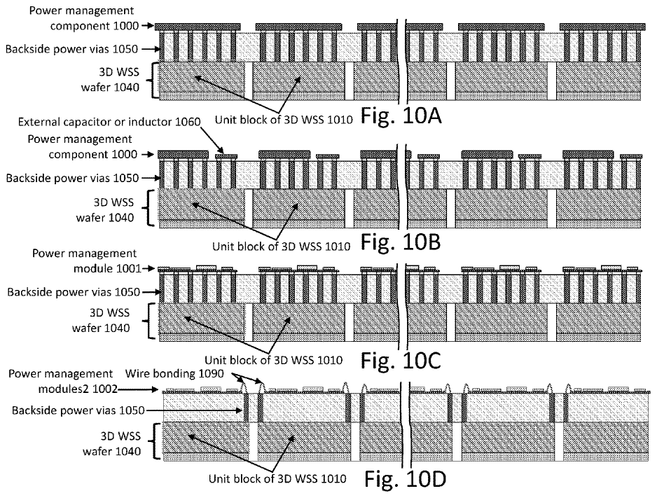

Similar to the diamond power transistors formed for the power gating in FIG. 7, the diamond power transistors could be integrated to form a power step-down converter. FIG. 9A illustrates various components integrated on a DHS layer for a power step-down converter. In addition to the diamond power transistors, a diamond diode could be integrated to form a power step-down converter. The formation processes of diamond-based diodes is described in at least Zimmermann, T., et al. “Ultra-nano-crystalline/single crystal diamond heterostructure diode.” Diamond and related materials 14.3-7 (2005): 416-420; Umezawa, Hitoshi, Yukako Kato, and Shin-ichi Shikata. “1 Ω on-resistance diamond vertical-Schottky barrier diode operated at 250° C.” Applied Physics Express 6.1 (2012): 011302; and Makino, Toshiharu, et al. “Diamond Schottky-pn diode with high forward current density and fast switching operation.” Applied Physics Letters 94.26 (2009): 262101, the entire contents of the foregoing are incorporated herein by reference.

Furthermore, a thin film inductor or capacitor could be integrated together with the diamond power transistors and diamond diode. By doing so, the voltage regulators could be monolithically integrated on the 3D WSS. The components integrated on DHS layer for DHS for power step-down converter may include at least one or more components such as, for example, diamond power transistor, diamond power diode, inductor, or capacitor as illustrated in FIG. 9A. The drawing in FIG. 9A does not mean to provide any specific circuit design but the specific design including layout and interconnect for the power step-down converter could be done by artisan in the art of low voltage DC power supply and power regulator designs, to be designed per the specific requirements of the 3D WSS. For example, a design configuration of an on-3D WSS power step-down converter could be DC-DC converter, Low-Drop-Out, linear regulator, switched-mode power supply, or other form of power regulator.

Further, some embodiments of the invention may also include an array of power step-down converters implemented on a 3D WSS. A multiplicity of power step-down converters may be distributed over the 3D WSS and each power step-down converter could regulate each node of the 3D WSS, and the node could be a block, die, unit, or other functional block. As illustrated in FIG. 9B, global power rails may be overlaid on the power gating DHS layer comprising the power step-down converters. Thus, the power management circuit, structure, layout, design and software could have high granularity and individually control each load block, or control groupings or group of load blocks.

In another embodiment, an interfacial layer could be added between a 3D WSS layer and a power gating layer, and this interfacial layer may comprise diamond. Because of the high density of heat generation per unit volume of the 3D WSS, efficient heat dissipation methods could be indispensable. For example, an efficient heat dissipation method/structure is a diamond heat spreader, which could be an efficient heat dissipation structure, design, layer, and layout. However, a difference of thermal expansion coefficients between the primary material of diamond for the power gate layer and the primary material of silicon for the 3D WSS layer may cause a thermal induced mechanical stress, which could cause long-term fatigue & possibly failure. In order to mitigate such a thermal stress, a buffer layer could be inserted between the two layers. Such a buffer layer could have its thermal expansion coefficient between diamond and silicon, which would mitigate the mismatch of thermal expansion coefficients. As well, a ‘slip’ layer could be formed (grown and/or deposited) between the buffer layer and each of the other two layers, such as, for example, the silicon 3D WSS layer and diamond power gating layer in the example above. Such a slip layer could include, for example, a thin (less than about 200 angstroms, less than about 100 angstroms) layer of silicon oxide, tin oxide, and similar materials known in the industry to help the structure thermally relax. Examples of the buffer layer could be, but not limited to, boron nitride, aluminum nitride, and gallium nitride, as supported by at least Xu, F., et al. “Microstructure and tribological properties of cubic boron nitride films on Si3N4 inserts via boron-doped diamond buffer layers.” Diamond and related materials 49 (2014): 9-13; Godbole, V. P., and J. Narayan. “Aluminum nitride buffer layer for diamond film growth.” Journal of materials research 11.7 (1996): 1810-1818; and Liu, Jin-long, et al. “Preparation of nano-diamond films on GaN with a Si buffer layer.” New Carbon Materials 31.5 (2016): 518-524, the entire contents of the foregoing are incorporated herein by reference.

Integrating the diamond level with the 3D WSS could be done using layer transfer and hybrid bonding techniques as presented herein and the incorporated by reference art.

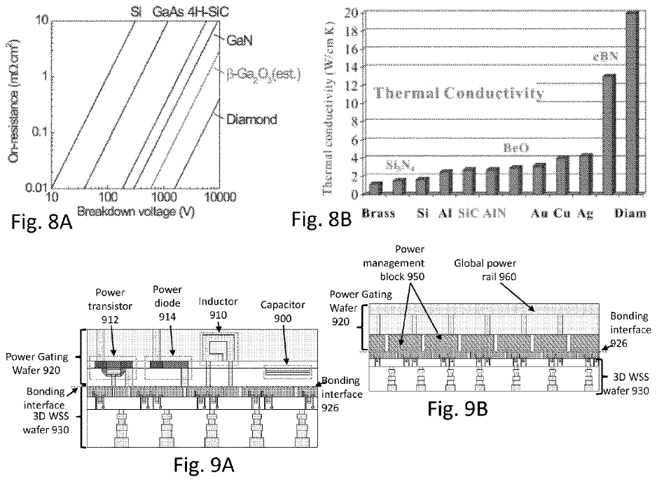

A paper by, Higashiwaki, Masataka, et al. “Gallium oxide (Ga2O3) metal-semiconductor field-effect transistors on single-crystal β-Ga2O3 (010) substrates.” Applied Physics Letters 100.1 (2012): 013504, incorporated herein by reference, shows a theoretical limit of on-resistance as a function of breakdown voltage of various semiconducting materials as shown in FIG. 8A. From this figure, the conduction loss of diamond device is a few orders of magnitude lower than those of SiC, GaN, and even GaO devices at the same breakdown voltage. This feature implies the diamond power transistor could be a superior option. In addition to the electrical properties, FIG. 8B shows thermal conductivity of various materials including copper and diamond. It is shown that the diamond shows far greater thermal conductivity compared to the well-known thermal conducting material such as copper. Therefore, the use of diamond material as a back-side power distribution backbone could simultaneously be an innovative choice for the power gating device as well as the heat spreader layer.

In some embodiments of the described invention, passive components, for example, such as capacitors 900 and inductors 910, are monolithically integrated with power transistor(s) 912 and power diode(s) 914 on the backside of DHS layers such as power gating wafer 920 and 3D WSS wafer 930 as illustrated in FIG. 9A. DHS layers such as power gating wafer 920 and 3D WSS wafer 930 may also be bonded, with metal to metal and oxide to oxide bonds being formed at the bonding interface 926, preferably thru hybrid bonding. At least one or more elemental components such as capacitor 900, inductor 910, transistor 912, and diode 914 are monolithically integrated to form at least one power management block 950. The power management block 950 could be one of a switching regulator, linear regulator, switched capacitor voltage converters, and voltage reference for the generation and control of regulated voltages required to operate the 3D WSS on 3D WSS wafer 930. As illustrated in FIG. 9B, those power management blocks 950 could be distributed for distributed power across unit blocks of 3D WSS wafer 930. Power and ground connections may be made to the power management block(s) 950 on the power gating wafer 920 with at least global power rails 960.

In some embodiments of the described invention, power management components 1000 which are separately manufactured from the 3D WSS wafer which include unit blocks of 3D WSS 1010 are attached on the backside of 3D WSS wafer 1030. The power management component 1000 could include distinct components, for example, such as transistor, diode, capacitor, and inductor, (not shown in FIG. 10m rather in FIG. 10A) and performs a function such as on/off a switching regulator, linear regulator, switched capacitor voltage converters, and may provide a voltage reference for the generation and control of regulated voltages required to operate the 3D WSS. The power management components 1000 within each unit block of 3D WSS 1010 could be distributed over the 3D WSS wafer 1030. As illustrated in FIG. 10A, the power management component 1000 could be one chip, which could be fully packaged or in bare die form. The power management components 1000 could be attached on the backside of the 3D WSS wafer 1040 by flip chip bonding including conductive connections from the power management component(s) 1000 by backside power vias 1050 to unit block of 3D WSS 1010. Alternatively, the power management components 1000 could be attached on the backside of the 3D WSS wafer 1040 using micro-bump interconnects which also include conductive connections from the power management component(s) 1000 by backside power vias 1050 (including micro-bump interconnects) to unit block of 3D WSS 1010. Alternatively, bump-less attachment techniques such as using direct bonding of dies to the backside of 3D WSS wafer 1040, or using hybrid bonding, or using fusion bonding.

In another embodiment of the described invention, a power management function could be attained through a multi-component approach. Particularly, power management component 1000 may integrate the entire converter except for one or more capacitors or inductors 1060. Instead, external inductor or capacitor 1060 could be separately (from the converter) prepared, which could then be co-integrated as illustrated in FIG. 10B. Such a design flavor could be desired when the power management system requires capacitance or inductance values that are harder to achieve by monolithic integration. The inductor 1060 could be an air-core inductor. Alternatively, the inductor 1060 could further include a magnetic-core or ferromagnetic-core. The capacitor 1060 could be tantalum or aluminum electrolytic capacitor. Alternatively, the capacitor 1060 could be multi-layer ceramic capacitor. The power management function thru the converter shown in FIG. 10B may also include at least 3D WSS wafer 1040 with unit blocks of 3D WSS 1010, backside power vias 1050, as well as the discussed external inductor or capacitor 1060 and power management component 1000.

In another embodiment of the described invention, a power management function could be implemented as a module and such power management modules 1001 could be stacked on the backside of 3D WSS wafer 1040 as illustrated in FIG. 10C. Typically, various microelectronic IC chips are mounted on the printed circuit board (PCB) to form a microelectronic system. Various PCB module or interposers could be mounted on a 3D WSS wafer 1040. Particularly, the power management modules 1001 could include various power management components such as power management IC(s) and various passive elements such as capacitors and inductors. Alternatively, the power management module 1001 could be 2.5D or 3D silicon or glass interposer mounting various power management components such as power management IC(s) and various passive elements such as capacitors and inductors. The PCB or interposer module could be dual sided so that the backside of its module could have a bump or micro-bump or even landing pads to connect to the backside via such as backside power via 1050 of a 3D WSS wafer 1040 an/or a unit block of 3D WSS 1010. The integration to the 3D WSS could include use of common techniques such as, for example, including low temperature soldering or bonding or hybrid bonding. The power management function shown in FIG. 10C may also include at least, backside power vias 1050, as well as the discussed power management modules 1001 and 3D WSS wafer 1040 with unit blocks of 3D WSS 1010.

In another embodiment of the described invention, a power management function could be implemented as a PCB module or interposer module. In some applications, the number of pins required for the power supply could be just a few, which may not require micro-bump or direct bonding. In such cases, as illustrated in FIG. 10D, the PCB or interposer module power management module2 1002 may contain various power management components such as power management IC and various passive elements such as capacitors and inductors could be a single sided module. The single sided module, power management module2 1002, could be simply mounted on the back side of the 3D WSS wafer 1040 with unit blocks of 3D WSS 1010 and electrical connections could be made through wire bonding to the backside power vias 1050. Electrical/conductive connections from the 3D WSS wafer 1040 and/or unit block of 3D WSS 1010 to the power management module(s) 1002 may be made by at least backside power vias 1050. Other backside vias, not shown, may also be present to connect control signals or other signals between the 3D WSS wafer 1040 and/or unit block of 3D WSS 1010 and the power management module(s) 1002.

One clear advantage provided by the diamond heat removal structure is the electrical isolation inherent aspect of the diamond material. It help keeping the simple the process to provide back-side power delivery with an excellent heat conductivity without concern of shorting power lines. According a power delivery diamond substrate could be formed as is illustrated in FIG. 2A-2H and FIG. 6A-FIG. 7C, by starting with a wafer been etched for future power rails, than forming diamond layer with such as CVD, than add in the power rail and CMP to remove the shorting access metal, than use hybrid bonding or metal to metal bonding and wafer transfer to transfer the ‘power delivery-heat spreader’ structure on the back of the target 3D system,

The power management function or module explained in at least FIG. 10A-10D may further include a built-in sensing function (not shown) which may gather information such as current, voltage, power, temperature of each unit. The built-in sensing function could offer protection features such as, under voltage lock out, over-current protection, and thermal shutdown.

The power management function or module explained in at least FIG. 10A-10D may further include a communication function via a system management bus (SMB) disposed (but not shown) between each unit block of 3D WSS 1010 of 3D WSS wafer 1040 and host (not shown). The communication function could exchange the information required for adjusting the power supply or shut down/restarting the power supply. Such options could be detailed in a design by artisan in the system integration and power management art.

Another embodiment of the described invention is related to a 3D WSS for radio frequency (RF) applications or a 3D WSS with RF communication functions. Such a 3D WSS uses an electromagnetic spectrum or radio wave to propagate a signal through space for data communication. More specifically, the RF communication uses at least one bidirectional RF link for using RF transceivers and RF receivers. Those RF transceivers and RF receivers could be monolithically integrated on a 3D WSS. Alternatively, the RF transceivers and receivers could be separately fabricated as a bare die, a wafer, a fully packaged chip, or a module, and then mounted directly on the base wafer of a 3D WSS, including techniques such as has been illustrated in at least FIG. 10A-10D. The frequency range of RF signals could be about 30 KHz to 300 GHz or even higher. The RF communication could also be used to communicate between neighboring 3D WSSs to form a clustered fleet of 3D WSS as a system. Alternatively, the RF communication could be used for remote-control or autonomous/inertial-control applications such as, for example, autonomous vehicles, home automation applications, security and defense applications, or industry-oriented applications.

In some embodiments of the described invention of the 3D WSS for Radio Frequency (“RF”) applications or a 3D WSS with RF circuits, a low-loss substrate could be preferably used. In order to minimize the RF loss, a portion of a silicon substrate of a 3D WSS could be replaced by a dielectric having a low RF loss. Currently, the typical silicon wafer thickness is approximately 700 μm, where only less than the top 100 μm is used for actual device fabrication and the remainder of the bottom thickness is necessary for mechanical support for successful wafer handling. In order to replace the high dielectric loss of silicon with a low loss dielectric material, a portion of the silicon substrate of a 3D WSS wafer containing an RF function could be replaced by a low loss dielectric.

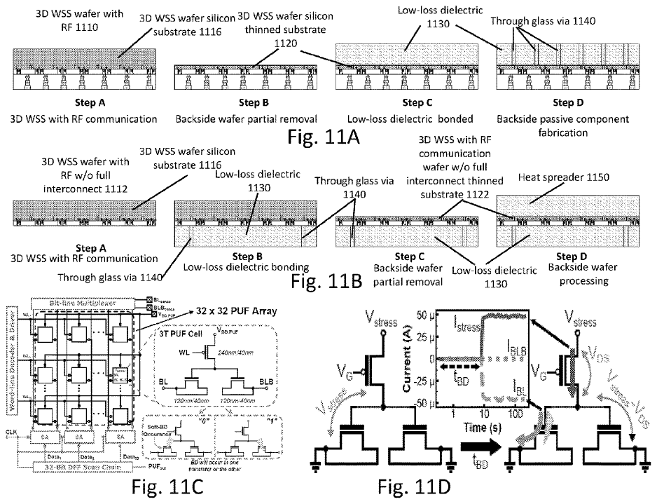

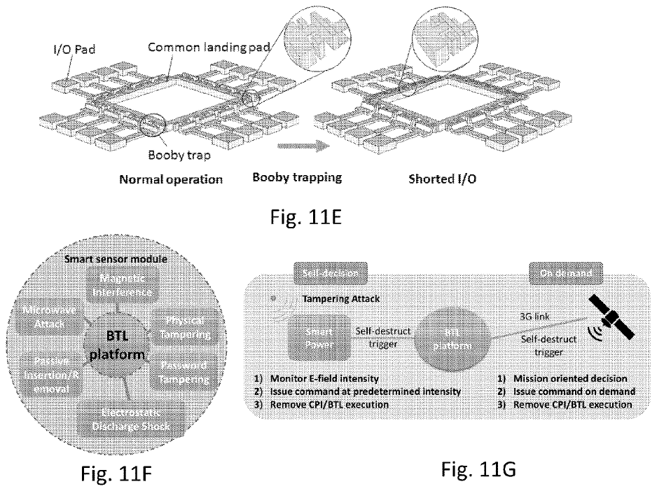

As illustrated in FIG. 11, a low loss dielectric, such as, for example, silicon dioxide deposited during wafer fabrication or a glass wafer bonded onto the 3D WSS wafer. Such a low loss dielectric layer could offer also mechanical strength for wafer handling. Furthermore, various passive components such as, for example, transmission lines, ground planes, antennas, could be fabricated on the low loss dielectric.

The low loss dielectric layer could be added to the backside of a 3D WSS as illustrated in FIG. 11A. A 3D WSS wafer with RF communication 1110 is fabricated (Step A) including 3D WSS wafer silicon substrate 1116. A substantial portion of the backside of 3D WSS wafer silicon substrate 1116 is removed (Step B), thus resulting in forming 3D WSS wafer silicon thinned substrate 1120. A substantial portion may include removal of about 80%, about 85%, about 90%, about 95%, about 98%, or about 99%, or about greater than 99% of the original thickness of 3D WSS wafer silicon substrate 1116. Techniques for silicon removal which provides a controlled and uniform removal may include, for example, mechanical backgrind, chemical etches such as, for example, sulfuric acid/nitric acid and sometimes hydrofluoric acid combinations, plasma silicon etches, which may include, for example, SF6 or other Fluoride based gases in an excited state, Reactive and/or non-reactive ion etching, for example, with gases such as Ar and N2, etch stop methods including SiGe, SiN, and silicon density manipulations, and other silicon etches known in the art. The final thickness of the remaining silicon of 3D WSS wafer silicon thinned substrate 1120 may be greater than about 5 nm, greater than about 10 nm, greater than about 15 nm, greater than about 20 nm, greater than about 25 nm, greater than about 50 nm, greater than about 100 nm, greater than about 500 nm, depending on engineering and design choices and desired substrate effects of the 3D WSS circuitry and devices.

A low RF loss dielectric 1130 is added to the backside of 3D WSS wafer silicon thinned substrate 1120, which provides both mechanical support and low dielectric RF loss (Step C). Optionally, a backside fabrication on the glass wafer could further be conducted to integrate through glass vias 1140, power vias, interconnects, transmission lines, integrated antennas, or other high-Q passive components (Step D). Alternatively, low dielectric loss layer 1130 could be added onto the front side of 3D WSS wafer silicon thinned substrate 1120. Such glass level to support RF circuits could be further processed such as presented by Tao, Jing, et al. “Large-Scale Fabrication of Surface Ion Traps on a 300 mm Glass Wafer.” physica status solidi (b) (2021): 2000589, the entire contents are incorporated herein by reference

As illustrated in FIG. 11B, a 3D WSS with RF communication wafer w/o full interconnect 1112 is fabricated (Step A). The 3D WSS with RF communication wafer w/o full interconnect 1112 could include a local and global interconnect layer. In Step B, a low loss dielectric 1130 layer may be added on the front side of the 3D WSS with RF communication wafer w/o full interconnect 1112 and fabrication on the low loss dielectric 1130 layer could further be conducted to integrate, for example, through glass vias 1140, power vias, other interconnect, transmission lines, integrated antennas, or other high-Q passive components (not shown). Optionally, a substantial portion of the backside of 3D WSS wafer silicon substrate 1116 is removed (Step C), thus resulting in forming 3D WSS wafer silicon thinned substrate 1120. A substantial portion may include removal of about 80%, about 85%, about 90%, about 95%, about 98%, or about 99%, or about greater than 99% of the original thickness of 3D WSS wafer silicon substrate 1116. Techniques for silicon removal which provides a controlled and uniform removal may include, for example, mechanical backgrind, chemical etches such as, for example, sulfuric acid/nitric acid and sometimes hydrofluoric acid combinations, plasma silicon etches, which may include, for example, SF6 or other Fluoride based gases in an excited state, Reactive and/or non-reactive ion etching, for example, with gases such as Ar and N2, etch stop methods including SiGe, SiN, and silicon density manipulations, and other silicon etches known in the art. The final thickness of the remaining silicon of 3D WSS with RF communication wafer w/o full interconnect thinned substrate 1122 may be greater than about 5 nm, greater than about 10 nm, greater than about 15 nm, greater than about 20 nm, greater than about 25 nm, greater than about 50 nm, greater than about 100 nm, greater than about 500 nm, depending on engineering and design choices and desired substrate effects of the 3D WSS circuitry and devices.

An additional supporting layer or heat spreader 1150, for example, including a diamond layer, could be added to the backside of 3D WSS with RF communication wafer w/o full interconnect thinned substrate 1122 (Step D).

The power delivery and the diamond heat removal and control structure could be integrated on top or inside the 3D system in a similar way as was presented for the liquid heat removal structure in PCT application US21/44110, incorporated herein by reference, such as in reference to its FIG. 16A-16E.

The 3D System as presented herein could include security circuit(s) and software to protect it from hackers or other undesired interferences. There are many security techniques that are well known in the art and could be integrated within such a 3D System. An additional option is to integrate within the 3D system one or multiple random number generated security keys to help support the 3D System security sub system. Such a key could be what is often been called “physically unclonable function” (PUF) as is illustrated in FIG. 11C which is copied from FIG. 2 of a paper by Chuang, Kai-Hsin, et al. “A physically unclonable function with 0% BER using soft oxide breakdown in 40 nm CMOS.” 2018 IEEE Asian Solid-State Circuits Conference (A-SSCC). IEEE, 2018, incorporated herein by reference in its entirety; additional teaching could be found in a publication by Chuang, Kai Hsin. “Highly Reliable Physically Unclonable Functions: Design, Characterization and Security Analysis.” (2020); and in a paper by Chuang, Kai-Hsin, et al. “A physically unclonable function using soft oxide breakdown featuring 0% native BER and 51.8 fJ/bit in 40-nm CMOS.” IEEE Journal of Solid-State Circuits 54.10 (2019): 2765-2776, incorporated herein by reference in its entirety, from which the bias condition as is illustrated in FIG. 11D is copied from its FIG. 3. At 40-nm CMOS this paper presents a 1024-bit PUF Array structure layout sized at 72 μm×48 μm. An alternative is presented in a paper by Lee, C., J. Lee, and Y. Lee. “Two-way oxide rupture scheme for PUF implementation in low-cost IoT systems.” Electronics Letters 56.20 (2020): 1047-1048, all of the above incorporated herein by reference in their entirety.

Such a PUF could be used as part of the 3D System such as is presented by Haj-Yahya, Jawad, et al. “Lightweight secure-boot architecture for risc-v system-on-chip.” 20th International Symposium on Quality Electronic Design (ISQED). IEEE, 2019, by Kaveh, Masoud, Diego Martín, and Mohammad Reza Mosavi. “A lightweight authentication scheme for V2G communications: A PUF-based approach ensuring cyber/physical security and identity/location privacy.” Electronics 9.9 (2020): 1479, by Nath, Atul Prasad Deb, et al. “System-on-chip security architecture and CAD framework for hardware patch.” 2018 23rd Asia and South Pacific Design Automation Conference (ASP-DAC). IEEE, 2018, and by Lounis, Karim, and Mohammad Zulkernine. “Lessons Learned: Analysis of PUF-based Authentication Protocols for IoT.” Digital Threats: Research and Practice (2021), and by Lounis, Karim. Security of Short-Range Wireless Technologies and an Authentication Protocol for IoT. Diss. Queen's University (Canada), 2021, all are incorporated herein by reference.

Other types of system security could be used as presented in a paper by Charles, Subodha, and Prabhat Mishra. “Reconfigurable network-on-chip security architecture.” ACM Transactions on Design Automation of Electronic Systems (TODAES) 25.6 (2020): 1-25; Charles, Subodha, and Prabhat Mishra. “Securing network-on-chip using incremental cryptography.” 2020 IEEE Computer Society Annual Symposium on VLSI (ISVLSI). IEEE, 2020; and Charles, Subodha, and Prabhat Mishra. “A survey of network-on-chip security attacks and countermeasures.” ACM Computing Surveys (CSUR) 54.5 (2021): 1-36; by Bahmani, Raad, et al. “{CURE}: A Security Architecture with {CUstomizable} and Resilient Enclaves.” 30th USENIX Security Symposium (USENIX Security 21). 2021; by Zhu, Jianping, et al. “Enabling rack-scale confidential computing using heterogeneous trusted execution environment.” 2020 IEEE Symposium on Security and Privacy (SP). IEEE, 2020; and by Lázaro, Jesús, et al. “Embedded firewall for on-chip bus transactions.” Computers & Electrical Engineering 98 (2022): 107707, all are incorporated herein by reference in their entirety.

The 3D System security could be done at multiple levels. First, securing the interface and the communication between, the 3D System and external elements. Then securing the X-Y communication between units, while using the X-Y communication fabric. Such X-Y level security could be incorporated within the communication processor as part of the communication protocol. Then additional security could be incorporated to the unit processors. And additional security could be integrated with a non-volatile memory controller to secure the stored memory. The security circuits could be done at many levels of complexity starting with simple encryption such as logic XOR with the PUF. For securing the content of the NV memory a smaller PUF such as 32 bit, which will need far smaller area, could be sufficient for many applications. A more complex approach including using schemes such as an RSM of public and private keys could be used to secure the input or output of the 3D System data stream. Such mix and match security could utilize techniques presented in the incorporated by reference art or other technique known in the art to an artisan in system security.

In some applications, such as mobile and airborne, use of 3D System additional measures could be integrated within the 3D System to protect its design and data from being physically attacked if captured by an aggressive competitor or even an enemy. Such protection could include measures such as erasing or destroying elements of the 3D System to a full destruction. Such measures have been presented in a paper by Tada, Sho, et al. “Design and concept proof of an inductive impulse self-destructor in sense-and-react countermeasure against physical attacks.” Japanese Journal of Applied Physics 60.SB (2021): SBBL01; by Wei, Yinghao, Bingqiang Li, and Qing Zhang. “Design and Implementation of a Key-Erase Control System.” Proceedings of the 5th China Aeronautical Science and Technology Conference. Springer, Singapore, 2022; by Kim, Sieun, Dowon Hong, and Ki-Woong Park. “Secure Disposable Computing Technology for Low-end Embedded Devices”; by Pandey, Shashank S., et al. “Self-Destructing Secured Microchips by On-Chip Triggered Energetic and Corrosive Attacks for Transient Electronics.” Advanced Materials Technologies 3.7 (2018): 1800044, all are incorporated herein by reference in their entirety.

Some of these techniques would need adding a built-in energy source to give the 3D System self energy to perform such self destruct even if the external power supply has been disconnected. Such self-energy could be, for example, store within the incorporated trench or stack capacitors which were added in for stabilizing the power supply within the chip as is presented in reference to FIG. 9A and FIG. 10B herein and in the incorporated by art references. Such could also include adding a dedicated battery, for example, such as a solid state battery as presented in a paper by Tan, Darren H S, et al. “From nanoscale interface characterization to sustainable energy storage using all-solid-state batteries.” Nature nanotechnology 15.3 (2020): 170-180, incorporated herein by reference in its entirety. An additional alternative is integrating a super-capacitor which could help stabilize the power supply during operation as well as provide energy for a self-destruct if needed. A subclass of super-capacitor are micro super capacitors which are designed to be integrated with a semiconductor device and could be a good fit for a 3D System, for example, such as presented in a paper by Vyas, Agin, et al. “Alkyl-Amino Functionalized Reduced-Graphene-Oxide-heptadecan-9-amine-Based Spin-Coated Microsupercapacitors for On-Chip Low Power Electronics.” physica status solidi (b) 259.2 (2022): 2100304, incorporated herein by reference in its entirety.

In some application a specific protection to the NV Memory, such as the 3D NAND memory, could be used. Such could include using PUF which could be a relatively small such as 64 bits to be integrated with the NV Memory M-System as part of the memory controller. Such could use the PUF to encrypt data stored in the NV memory or the addressing of the memory, and decrypt it at the readout. Such could include a protection measured to protect against physical tampering, especially for a mobile 3D System. A system to secure storage is presented in at least US patent U.S. Pat. No. 9,397,834, and US application: US 2019/0384938, and Chinese applications CN201711278280, CN108182371, and PCT application WO2019109967, all are incorporated herein by reference in its entirety. An alternative measure is to erase the PUF to protect the NV data from being stolen. FIG. 11D illustrates a bias condition to initialize a PUF leveraging the random effect of the oxide breakdown process. Following the initialization of a PUF structure at every PUF cell one of the transistor has its gate oxide broken. To erase the PUF a destruction cycle could be activated to break the oxide of the non broken transistor resulting with an erased PUF. One option is to perform a cycle similar to the initialization process one time with BL side grounded and BLB floating thus breaking all of the non broken BL side transistor gate oxides and then a second cycle with the inverse bias condition having the BL side floated and BLB side grounded thus breaking all of the non broken BL side transistor gate oxides. Such PUF erase could be done very quickly and with low energy such as what could be kept in the capacitor or backup battery securing the NV data from being stolen.

In some cases multiple PUF resources could be available to support resuming proper operation after a PUF erasing, if so is warranted. Alternatively a PUF could be constructed with an RRAM type technology to allow reset of an erased PUF to allow re initialization.

The 3D System as presented herein could be constructed on as a small device such as 5×5 mm² or bigger device like reticle size or large device like wafer scale such as about 250×250 mm² or even panel level as previously presented. The choice of security measure could be designed as based on the 3D System structure and the application needs which may be very different if it is to be a computing resource at a server farm vs. if it is an airborne computer within a drone serving in a military application across enemy lines. An artisan in the art could design such specific security solution using the art presented here to fit the need of the specific implementation.

An embodiment of a self-destructing 3D system with a controlled and triggerable manner is presented. Malicious modification of integrated circuits (ICs) is referred to as ‘Hardware Trojan’ has emerged as a major security concern. The Hardware Trojan can alter functional behavior, which results in disastrous consequences in military and security critical applications. The hardware Trojan can be inserted during design or fabrication. Even though the devices used by our military are designed by a credible US company located in Silicon Valley or elsewhere in the USA, we should realize that most of the US chipmakers rely on a handful of outside foundry services based in China, Taiwan, and South Korea for their fabrication and/or for their data-processing for mask-making. Although there is no reason to suspect that these foundries are adding malicious hardware, it is also impossible to exclude any possibility that they might make undesirable adjustments to the designs to gain asymmetric advantage or nullify our capabilities. To this end, in one embodiment, a self-destructing function which can physically terminate the designed function or the security key portion of the IC is described. Such a self-destructing function could be called the booby-trap layer (BTL). The BTL can be implemented separately from the IC fabrication, and therefore applicable to any types of chips fabricated in any foundry. This implies that the fabrication of a BTL may be implemented on US soil and in a US company or organization to place a BTL on top (or bottom) of the fully processed chip or wafer from any foundry anywhere in the world. It should be noted that the US is used here as an example and that the same concepts could be applied in respect to other nation or entities.

One example of a booby trap layer is presented as follows. The BTL layer fabrication technology uses a microelectromechanical system (MEMS) technology during the IC packaging process. The BTL technology is somewhat similar to a mechanical fuse system. When the trigger is activated, all input/output (I/O) pins are shorted by welding. As a consequence, the IC will be irreversibly self-destructed. The IC circuits use metal input/output pins to place and route the electric signal. The proposed technology uses a mechanically bendable metal booby trap that connects to the I/O pins. The fabrication process could be added in a standard packaging process such as a redistribution layer (RDL). The RDL is an extra metal layer on a chip that is used for the formation of the IO pads of an integrated circuit available in other locations. The RDL process is readily available in US based facilities.

The I/O pins stay during any normal operation as designed. When the death of the chip is determined, all Critical Program Information (“CPI”) is removed followed by a BTL destroy command. Wiping out all data stored in a device protects from reverse engineering efforts even in electrically inoperable chips. In order to make a device non-operable, a trigger voltage is applied to a trigger contact or electrode and thus bends to contact and permanently stick to a metal landing pad as is illustrated in FIG. 11E. The structure of the BTL shown in FIG. 11E is one example and it should be understood that multiple variations could be made. Once the two metals stick together, they tend to stick permanently due to van der Walls force, a phenomenon long known as a ‘stiction mechanism’. The result of self-destruction is the formation of short circuit or abnormal signal, terminating the designed chip function.

One can argue that any kind of non-volatile switching element can be used as booby trap device. The floating-gate type transistor is not applicable since the transistor fabrication belongs to front end process. The non-volatile switching elements that can be made in back-end process may include, for example, metal fuse, oxide anti-fuse, resistive switching elements such as a metal-insulator transition. But they face many fundamental limitations. The operation of the fuse is based on the Joule heating mechanism, which requires a significant current flow, generally greater than a few mA. Since the destruction function may be necessary even when the external power supply is interrupted, it is preferable if the destruction device is operable with a low amount of energy, say, an integrated capacitor level energy. Therefore, if the supply power is not enough, the fuse-type device may not be appropriate for self-powered destruct function. In this regard, the proposed mechanical switch is desirable because the mechanical switch uses the smallest switching energy among all types of switching devices including the resistive switch, e-fuse, anti-fuse and flash memory. The resistive switching elements include phase change, Metal Insulator Transition (“MIT”), memristor, and magnetic switching materials. Those candidates require exotic materials that have yet technically matured. The proposed approach is a variation of existing process technologies allowing a cost effective fabrication. For example, the technology does not use anything exotic such as carbon nanotubes or graphene, which could take significant development time before it can be implemented in military applications. Instead, the technology still revolves around silicon and the standard integrated circuit manufacturing. In addition, the resistive switching materials are often weak at tampering. The material that uses the oxygen vacancy or filament formed in the oxide, which implies that the anti-fuse, MIT, and mersister can be recovered by high temperature annealing. Therefore, the anti-fuse type device can be tampered with deliberately or accidentally. In contrast, the present mechanical device is catastrophic and irreversible once the metal function is made.

Mechanical switch devices; however, do comply with all the critical requirements for the booby trap purpose. Such mechanical switches are known in the art such as presented in a paper by Cao, Tongtong, Tengjiang Hu, and Yulong Zhao. “Research status and development trend of MEMS switches: A review.” Micromachines 11.7 (2020): 694; by Qian, Chuang, et al. “Sub-100 mV computing with electro-mechanical relays.” IEEE Transactions on Electron Devices 64.3 (2017): 1323-1329; and by Chen, I-Ru, et al. “Nanomechanical switch designs to overcome the surface adhesion energy limit.” IEEE Electron Device Letters 36.9 (2015): 963-965, all are incorporated herein by reference in their entirety. In most cases there is effort and special process step design to reduce the sticking of these mechanical switches. For the application of mechanical switches for BTL sticking is desired. Since sticking is the natural tendency of these mechanical relays an artisan in the art could adapt the fabrication process to support such sticking to form an effective BTL. For simplicity of integration the MEMS process to form a level of mechanical switches (often called relays) could be attained by forming an M-Level which will be integrated in the 3D System utilizing layer transfer techniques as presented herein and the incorporated by reference art.

Mechanical switches could be integrated in a 3D System such as for the implementation of a switch fabric 360 or a routing fabric 386. Mechanical switches could be integrated in a 3D System as a security measure, a data bus, or as an address bus scrambling box. The connectivity of such scrambling box could be stored in a small dedicated non volatile memory which could be easily erase in case of security concern or by utilizing a dedicated PUF which could be fully activated as presented before in case of security concern, such could include switching on or off all the un-switched mechanical switches to fully protect the 3D System.

Mechanical switches could be integrated in a 3D System as part of a programmable interconnect for a programmable logic fabric. In the art a company named eASIC, which later was acquired by Intel, has used a via programmable interconnect with a LUT base programmable logic. A similar form of programmable logic could use an array of mechanical switches for the construction of the programmable interconnect as an alternative to the via defined interconnect. And in case of a security concern, the mechanical switches could all be switched on or off for securing the 3D System hardware design. In all these cases the mechanical switches could be an attractive option due to the very low energy required to switch them.

There are variations of mechanical switch technologies which been formed by a conventional semiconductor process utilizing “air gap” technology such as presented in a paper by Peschot, Alexis, Chuang Qian, and Tsu-Jae King Liu. “Nanoelectromechanical switches for low-power digital computing.” Micromachines 6.8 (2015): 1046-1065; Osoba, Benjamin, et al. “Sub-50 mV NEM relay operation enabled by self-assembled molecular coating.” 2016 IEEE International Electron Devices Meeting (IEDM). IEEE, 2016, Qian, Chuang, et al. “Sub-100 mV computing with electro-mechanical relays.” IEEE Transactions on Electron Devices 64.3 (2017): 1323-1329 and in a review paper by Jasulaneca, Liga, et al. “Electrostatically actuated nanobeam-based nanoelectromechanical switches—materials solutions and operational conditions.” Beilstein journal of nanotechnology 9.1 (2018): 271-300, all of the forgoing are incorporated herein by reference in their entirety.

In a 3D System utilizing wafer transfer technology heterogeneous integration is a key enabling technology allowing integration of level source from a process lines that could be different using tools and process that could be compatible or not but yet could be integrated with good vertical connectivity using the technologies presented here and in the incorporated by reference art. Such could include a mechanical switches level such as nano-electro-mechanical (NEMS) relays such as presented in a paper by Muñoz-Gamarra, Jose Luis, Arantxa Uranga, and Nuria Barniol. “CMOS-NEMS copper switches monolithically integrated using a 65 nm CMOS technology.” Micromachines 7.2 (2016): 30; by Jothiramalingam, Kulothungan, et al. “Stacking of nanocrystalline graphene for nano-electro-mechanical (NEM) actuator applications.” Microsystem Technologies 25.8 (2019): 3083-3089; by Baek, Gwangryeol, Jisoo Yoon, and Woo Young Choi. “Tri-state nanoelectromechanical memory switches for the implementation of a high-impedance state.” IEEE Access 8 (2020): 202006-202012; by Usai, Giulia. Design and Fabrication of 3D Hybrid CMOS/NEM relays technology for energy-efficient electronics. Diss. Université Grenoble Alpes, 2019; by Tazin, Nusrat, Daniel G. Saab, and Massood Tabib-Azar. “Back-end-of-the-line MEMS switches for power management, ESD and security.” (2018); by Jasulaneca, Liga, et al. “Fabrication and Characterization of Double-and Single-Clamped CuO Nanowire Based Nanoelectromechanical Switches.” Nanomaterials 11.1 (2021): 117; by Pandiyan, P., G. Uma, and M. Umapathy. “Design and simulation of electrostatic NEMS logic gates.” COMPEL-The international journal for computation and mathematics in electrical and electronic engineering (2018); and by Usai, Julia. Monolithic 3D hybrid design and fabrication of CMOS co-integrated NEMS relays. Diss. Grenoble Alpes University (ComUE), 2019, all of the forgoing are incorporated herein by reference in their entirety.

Some of the art detailing construction of an FPGA devices using such mechanical switches is presented in a paper by Han, Sijing, et al. “Ultra-low power NEMS FPGA.” Proceedings of the International Conference on Computer-Aided Design. 2012; by Qin, Tian, et al. “Performance analysis of nanoelectromechanical relay-based field-programmable gate arrays.” IEEE Access 6 (2018): 15997-16009; and by Yoon, Jisoo, Hyug su Kwon, and Woo Young Choi. “Multi-Layer Nanoelectromechanical (NEM) Memory Switches for Multi-Path Routing.” IEEE Electron Device Letters 43.1 (2021): 162-165, all of the forgoing are incorporated herein by reference in their entirety.

Some of these papers teach how to use such mechanical switches in order to form a memory array. Such teaching could be used to form a switch matrix which could be used, for example, as a data bus or memory bus rerouting box as a security measure. Such memory oriented papers are presented in a paper by Pamunuwa, Dinesh, et al. “Theory, Design, and Characterization of Nanoelectromechanical Relays for Stiction-Based Non-Volatile Memory.” Journal of Microelectromechanical Systems (2022); by Kang, Min Hee, and Woo Young Choi. “Dynamic slingshot operation for low-operation-voltage nanoelectromechanical (NEM) memory switches.” IEEE Access 8 (2020): 65683-65688; by Tatum, Lars Prospero, Urmita Sikder, and Tsu-Jae King Liu. “Design technology co-optimization for back-end-of-line nonvolatile NEM switch arrays.” IEEE Transactions on Electron Devices 68.4 (2021): 1471-1477; by Yoon, Chankeun, et al. “Device Design Guideline for HfO₂-Based Ferroelectric-Gated Nanoelectromechanical System.” IEEE Journal of the Electron Devices Society 8 (2020): 608-613; by Mahdi, Luay, and Qais Al-Gayem. “Design, simulation and testing of an array of nano electro mechanical switches (NEMS).” Indonesian Journal of Electrical Engineering and Computer Science 22.1 (2021): 113-120; by Veksler, Dmitry, et al. “Memory update characteristics of carbon nanotube memristors (NRAM®) under circuitry-relevant operation conditions.” 2020 IEEE International Reliability Physics Symposium (IRPS). IEEE, 2020, all of the forgoing are incorporated herein by reference in their entirety.

Such switches could also utilize carbon nano tubes (CNT) as presented in a papers such as by Mu, Weihua, Zhong-can Ou-Yang, and Mildred S. Dresselhaus. “Designing a double-pole nanoscale relay based on a carbon nanotube: A theoretical study.” Physical Review Applied 8.2 (2017): 024006.

In one embodiment, the self-destructing function can be applied to a remote armament system. The key goal of the anti-tamper is a remote system for autonomous tactical movement and even unmanned missions. The capability of the remote system could include the ability to activate the self-destruction function even if the power supply has ceased to function. So, it can be battery-operated, but ultimately even a battery-free operation will be desirable as it can increase the lifespan and reliability. In order for battery-free operation, a remote power/energy delivery could be used. The type of remote power delivery could be WiFi energy harvesting, RF energy harvesting, or movement energy harvesting, depending on use case and other engineering considerations.

The BTL microsystem is a ‘platform’ so it can be integrated with any other smart sensor module to monitor mission critical electronics depending upon applications and security level. So, in one embodiment of 3D system, the smart sensor module constantly monitors mission critical electronics such as tampering activities. Upon the arise of a need, the sensor issues a command to remove CPI and execute BTL. The command may be issued through an optical link due to its high immunity against high power microwave attack. The BTL platform could be made as an M-Level and integrated as part of the 3D system. The BJT shorting could be applied to the 3D System vertical buses.

The smart sensor module can be either a single or collective form of sensors for gathering external information and decision making. For instance, the smart sensor module can include a microwave power detector to monitor for high-power microwave attacks. Furthermore, the smart sensor can be extended to deal with various other tampering methods including physical breaking, magnetic interference, bypassing currents, removing wires, adding passive devices to cause interference, and electrostatic shock. Thus, the present BTL can be a platform that can be integrated with any form of smart sensor module upon a determined mission-oriented necessity.

A dual mode self-destruction is another embodiment. One way is the 3D system's self-decision based as explained in FIG. 11F and another is mission oriented and remote based. A possible application scenario of the self-destructive chip is the remote on-demand triggering of the self-suicide chip as illustrated in FIG. 11G. The self-suicide chip can be a multi-chip module consisting of a minimal energy storage device such as integrated capacitor, wireless communication device such as ultra-low power 3G module, the BTL, and the control circuitry. The capacitor powers both the 3G module and the self-destructing mechanism while the 3G module is on standby to receive the remote order. If a kill order is made for reasons of tampering, loss, theft and others, the control circuitry triggers the shatter operation terminating the designed function of the chip. Such self-destruction and sensor based activation could also include the destruction or erasing of the 3D System PUF elements as presented in reference to FIG. 11D.

Some embodiments of the invention may include alternative techniques to build IC (Integrated Circuit) devices including techniques and methods to construct 3D IC systems. Some embodiments of the invention may enable device solutions with far less power consumption than prior art. The device solutions could be very useful for the growing application of mobile electronic devices and mobile systems such as, for example, mobile phones, smart phone, and cameras, those mobile systems may also connect to the internet. For example, incorporating the 3D IC semiconductor devices according to some embodiments of the invention within the mobile electronic devices and mobile systems could provide superior mobile units that could operate much more efficiently and for a much longer time than with prior art technology.

Smart mobile systems may be greatly enhanced by complex electronics at a limited power budget. The 3D technology described in the multiple embodiments of the invention would allow the construction of low power high complexity mobile electronic systems. For example, it would be possible to integrate into a small form function a complex logic circuit with high density high speed memory utilizing some of the 3D DRAM embodiments of the invention and add some non-volatile 3D NAND charge trap or RRAM as described in some embodiments of the referenced and incorporated patents and patent publications and applications. Mobile system applications of the 3DIC technology described herein may be found at least in FIG. 156 of U.S. Pat. No. 8,273,610, the entire contents of which are incorporated by reference.

Another alternative relates to 3D NOR structures. Within U.S. Pat. No. 11,018,156 and within PCT application PCT/US21/44110, incorporated in their entirety herein by reference, a 3D NOR memory and fabrication flow was presented. The presented 3D NOR structure utilizes a vertical S/D (Source/Drain) and side gates. The alternative structures and flow which are presented in the following below herein utilize a similar 3D NOR memory structure, having vertical S/D, but instead of side gates the device structure utilizes top and/or bottom gates.

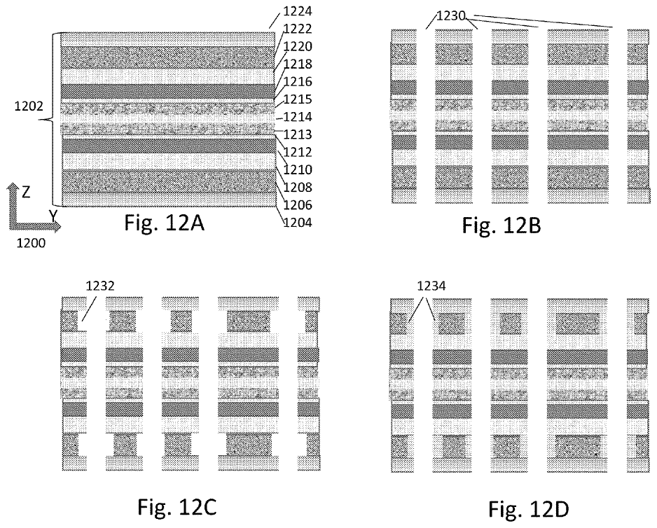

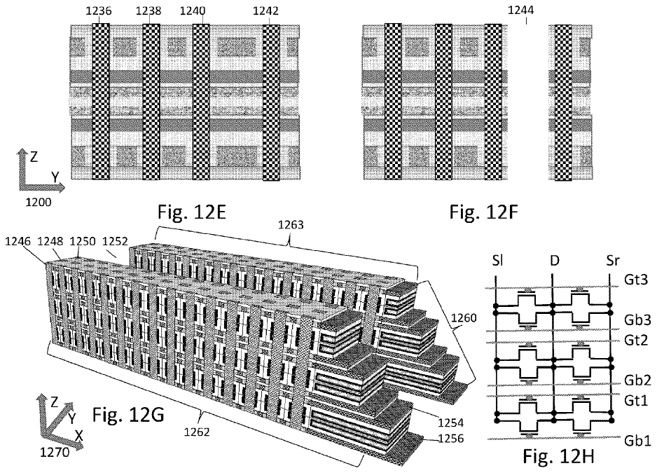

A flow for construction such 3D NOR memory, been described in the following with reference to FIG. 12A-12G. FIG. 12A-12F are vertical cut-views as indicated by Z-Y cardinal 1200. The 3D NOR memory portion of the device flow could start by processing successive layer depositions using planar deposition techniques, for example, such as CVD, on top of a substrate (not shown for clarity). FIG. 12A illustrates such a multilayer structure having first an isolation layer 1204 (for example silicon dioxide) overlaid by a bottom gate layer 1206 which could be a heavily doped poly silicon layer or tungsten layer, overlaid by a gate oxide layer 1208, overlaid by a charge trap layer 1210 such as nitride overlaid by an optional tunneling oxide 1212. The tunneling oxide 1212 could be very thin, for example, such as less than 4 nm, or be skipped leaving it to some minimal native oxide of charge trap layer 1210 (and/or 1218) to support high speed memory. This has been presented in incorporated by reference art in respect to memories named 3D NOR or 3D NOR-P. A poly silicon layer 1213 could be deposited next, which could eventually function as the bottom channel of the future memory transistor; then isolation layer 1214 (for example, silicon dioxide) and the upper channel 1215 (for example, a similar makeup as bottom gate layer 1206) may be deposited. And then similar functional layers such as upper tunneling oxide 1216, upper charge trap layer 1218, upper oxide layer 1220, upper top gate layer 1222, and upper isolation layer 1224 may be formed to produce the order and overlayment shown in FIG. 12A. These ‘upper’ layers may be similar in function with the described ‘lower’ layers; however, some or all of these upper layers may be processed differently than the prior ‘similar functional layers’). Multilayer structure 1202 could be processed/formed multiple times and overlaying each other to support more stacks of memory transistors in the vertical (z) direction.

Then a step of punching holes/trenches etc. utilizing lithography coupled with physical and chemical etch techniques to selectively remove the desired material may take place, thus forming holes 1230 as illustrated in FIG. 12B. These holes 1230 will be used to selectively replace some undesired portion of layers such as a region of a gate layer with another desired material such as a dielectric. Furthermore, such holes 1230 would be filled by conductive material to thus form the Source and Drain (S/D) pillars, for example, such as common Drain pillar 1238 in FIG. 12E.

As illustrated in FIG. 12C, then a step of selective etch 1232 of the upper top gate layer 1222 and bottom gate layer 1206 through the punch holes 1230 could take place. If heavily doped polysilicon were used for the upper top gate layer 1222 and bottom gate layer 1206, the polysilicon etch rate dependence on the doping concentration would be utilized to selectively remove the heavily doped polysilicon gate while leaving behind the lightly or undoped polysilicon channel. The etch rate dependence on the doping concentration of the silicon or polysilicon could be found in various literatures such as Lee, Young H., Mao-Min Chen, and A. A. Bright. “Silicon Etching Mechanisms-Doping Effect.” MRS Online Proceedings Library (OPL) 38 (1984); or Baldi, L. and D. Beardo. “Effects of doping on polysilicon etch rate in a fluorine-containing plasma.” Journal of applied physics 57.6 (1985): 2221-2225, the entire contents of both are incorporated herein by reference.

Then a step of indent dielectric fill 1234 with a dielectric, for example silicon dioxide, may be followed by an anisotropic etching of the dielectric for hole opening could take place as is illustrated in FIG. 12D. These gate indent etches are at least performed to avoid shorts of the gate lines with the subsequent S/D pillars.

Then a step of S/D fill could now take place to form common Drain pillar 1238 with left side Source 1236 and right side source 1240 and 2nd left side Source 1242 as illustrated in FIG. 12E. The structure could be use common Drain pillar 1238 with left side Source 1236 and right side source 1240, and the structure could start again with left side Source 1242 with trench 1244 disposed in-between each repeat as illustrated in FIG. 12F. Consequently, the memory cell configuration may be a mirrored cell structure with a shared Drain pillar.

FIG. 12G is a 3D (x, y, z cardinal 1270) illustration after processing stair-case 1260 for gate line access 1256 at the edge of the memory row 1262. Trench 1252 may be disposed in between two memory rows, for example, memory row 1262 and second memory row 1263. Each row could have multiple sets of memory columns each with shared drain pillar 1248 and left side Source 1246 pillar and right side source 1250 pillar.

The specific size of each element of the 3D NOR memory structure could be designed to meet process rules and to optimize device function and cost. The S/D pillars (1246,1248,1250) could have a diameter of about 5 nm or larger. The bottom channel (1213) or the top channel (1215) could have a thickness (Z direction) of about 5 nm or larger and length (Y direction) of about 10 nm or larger. The charge trap layer (1210,1218) could have a thickness of about 2.5 nm or about 3 nm or larger, the blocking gate oxide could have a thickness of about 4 nm or larger, and the tunneling gate oxide (1212,1216) could have a thickness of about 4 nm or thinner. The gate lines could have a thickness of about 5 nm or larger. The trench 1252 could have a size in Y direction of about 5 nm or larger.

FIG. 12H is a transistor schematic in the ZY plane of a small slice of the 3D NOR structure. Gb1 corresponds to the bottom gate line of the first level 1256, Gt1 corresponds to the top gate line of the first level 1254, Sl corresponds to the left source pillar 1246 and Sr corresponds to the right source pillar 1250 and D corresponds to the shared drain pillar 1248.

The number of layers in the stack would be subject to the size of the holes and the choice of layer thickness and limited by the available deep etch aspect ratio. Similar to 3D NAND, stacking of sub-stacks could be used to build taller structures.

One challenge of the flow presented in reference to FIG. 12A-12G herein is the need for many steps of layer depositions which constrains the total process time to be linear to the number of memory levels. The following flow presents an alternative in which sacrificial layers are used and then replaced with an atomic layer deposition (“ALD”) step in which a layer deposition step simultaneously provides a layer to many levels of memory-which could be referred to as a ‘shared deposition flow’.

FIG. 13A illustrates a multilayer structure to support construction of a 3D NOR structure for which the final structure is similar to the 3D NOR structure illustrated in FIG. 12G. It shows three pairs of designated channel levels 1304. The multilayer could be formed by epitaxial growth of single crystalline SiGe layers for the sacrificial films 1306, 1308 and silicon level for the channel layers 1304 such that the channels could be single crystal silicon. As an option in order to provide an etch selectivity between first SiGe sacrificial layer 1306 and the second SiGe sacrificial layer 1308, the stoichiometry of SiGe could be different. Alternatively, it could be a dielectric for sacrificial films 1306, 1308 and such as a lightly doped or undoped polysilicon for the channel layers 1304. In order to provide an etch selectivity between first sacrificial layer 1036 and the second sacrificial layer 1038, different type of dielectrics could be used, for example, oxide for one and nitride for another. The thickness of 2^{nd} sacrificial film needs to be high enough, to allow replacement with double layers of ONO (gate Oxide-charge trap Nitride layer-tunneling Oxide layer) and double layer of gates and isolation layers in between. The thickness of the 1^{st} sacrificial layer needs to be small enough to be filled by the double O—N—O layers but high enough to allow independent operation of each channel or minimize electric interference of the programmed states between top and bottom channels. The difference in the thickness of the 1^{st} sacrificial layer vs. the 2^{nd} sacrificial layer could be use to support a flow in which there is not much selectivity between these layers, so both layers would be removed in the etch step while during the following deposition step the ‘interchannel’ space would be fully filed up with ONO layers enabling the proper functionality of the structure.

FIG. 13B illustrates forming a punch holes and filling them with support pillars 1310 to hold the channel layers while the sacrificial layer are been etched out. These support pillars 1310 and the additional layers that would be deposited on them would be etched out after the deposition steps have fully replaced the sacrificial films. The support pillars could be spilt to groups or be replaced with new during the deposition steps to reduce the area waste associated with them. The details for such could be engineer by artisan in the process and be subject to the specific 3D NOR structure and the layer thickness.

FIG. 13C illustrates the structure after forming Small holes 1312 and Big holes 1314. Both Small holes 1312 and Big holes 1314 could be patterned in the same step. Both holes are for the release—etch away the sacrificial films. The Small holes are for auto-formation of isolation between successive memory transistors channels. The small holes are to be small enough to be sealed during the ONO deposition. For example, the size of small holes would be slightly smaller than two times the ONO thickness so that the small holes are closed after depositing ONO. The Big holes need to be big enough to support complete depositions of ONO gate and isolation which will be the complete replacement of the 2^{nd} sacrificial films 1308 by subsequent gate and inter-gate dielectric.

While not shown small holes could be also be desired and implemented in the structure illustrated in FIG. 12G the ‘non-shared deposition’ process flow.

In some structures the channel regions of the individual transistors of the same ridge of the same level could still be connected even after the formation of the small holes 1312. For those structures an additional option is to enable negative bias at the time the transistors in the ridge are not been accessed. Such ‘idle’ controlled negative bias could be helpful to extend the retention time of the memory via a high enough negative bias keeping the stored electrons in the charge trap regions to be leaked out. Such an option could include adding properly controlled connections to these channel regions to be activated during idle time.

FIG. 13D illustrates the structure after the release of the 2^{nd} sacrificial film. In many cases both the 1^{st} sacrificial film and the 2^{nd} sacrificial film could be released to together, resulting with the structure illustrated in FIG. 13D.

FIG. 13E illustrates the structure after the completion of the ONO deposition sealing the small holes and the narrow spaces between the semiconductor films which used to be filled by the 1^{st} sacrificial film. In some cases, at this stage some support pillars could be removed as the horizontal plates are firmer and could be structurally sustained with less support pillars (not shown). The ONO layers could include a very thin tunneling oxide or even skip it, a thin nitride layer of about 3 nm thickness and about 4-5 gate oxide. The ALD deposition of the ONO layers could affect multiple memory level-hence the shared deposition.

FIG. 13F illustrates the structure after deposition of the gate layer 1322 and the isolation layer 1324 forming the inter-gate dielectric. The gate material could be highly doped polysilicon or tungsten at about 5-8 nm thickness.

FIG. 13G illustrates the structure after etching holes for Source and Drain pillars (S/D)—punch holes.

FIG. 13H illustrates the structure after performing a selective etch of the gate material through the S/D holes to indent it and remove it from being in contact with the future S/D pillars. This step could be followed by an oxide deposition to fill oxide at the indent location and then performing an etch step to expose the channels to be connected to the S/D pillars, which is similar to the step described in FIG. 12B-12D.

FIG. 13I illustrates the structure after deposition of the S/D pillars 1330. The S/D pillars could be formed as metallic to enable Schottky barrier S/Ds for a much greater programming speed as previously detailed in the incorporated by reference art.

FIG. 13J illustrates the structure after etching away the support pillars and forming trenches 1342 between memory ridges 1344. Each memory ridge could include a row of memory structure with SI-D-Sr pillars similar to the structure of FIG. 12G and the schematic of FIG. 12L. At the edge of a memory ridge a staircase structure 1346 could be formed to support individual access to each gate line.

FIG. 13K illustrates an enlarged 3D view of 4 memory cells. 2 memory cells are controlled by bottom gate line 1352 and 2 memory cells are controlled by top gate line 1354. And the four memory cells are controlled by a shared Drain pillar 1356.

An additional option is to leverage the substrate for the memory structure to include select transistors for all of the S/D pillars or some of them. The memory structure could be aligned to a predefined structure in the carrying substrate. These could be select transistors for the S/D pillars. The formation of the S/D pillar holes could include exposing an array of contacts to the buried select transistors so the following deposition of the S/D pillars could also form connections to these buried select transistors.

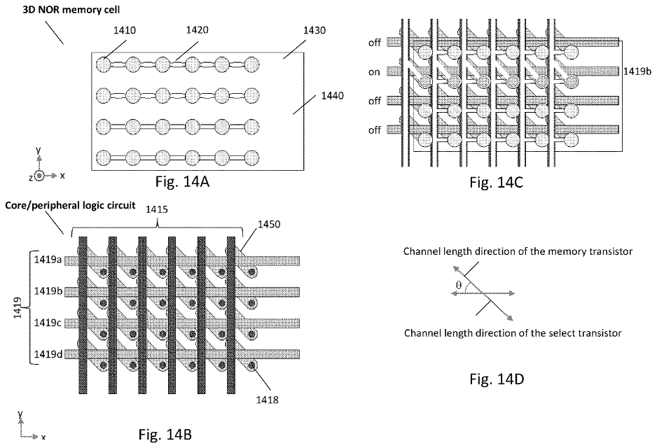

In the following alternative concept for integrating select transistors with a 3D NOR structure are presented. In FIG. 14A, a layout view of a 3D NOR memory cell is shown. The vertical pillar of source and drain could be vertical control lines 1410. Such vertical control lines could be a Bit Line (“BL”), a Source Line (“SL”), or a Ground Line (“GL”). The channel 1420 of the memory cell transistor could be formed in the horizontal direction. The gate of the channel could also be formed horizontal direction. The gate of the memory cell transistor could also be called to wordline 1430 which could be a sheet controlling a matrix of channels in X and Y direction similar to what is common in 3D NAND. The wordline 1430 could control multiple memory cells arrayed in both x-direction as well as y-direction. Therefore, the wordline 1430 could be understood as a wordline plane. At least one side of a wordline 1430 plane, some area would be reserved for the staircase contact 1440, which contact could be connected to a row address decoder of a control logic circuit. So, when a wordline 1430 plane is selected, multiple memory cells along x-direction and y-direction could be accessed. However, in order to activate only one row of the memory array, select transistors could be added to connect vertical control lines 1410 such as BLs and SLs of only one row in a WL 1430 with BLs and SLs of the control logic circuit.

FIG. 14B shows a layout view of a select transistor array. The array of select transistors could be a part of core and peripheral logic circuits. In order to distinguish the BL and SL in 3D NOR memory cell and BL and SL in control logic circuit, they are referred to zBL and zSL for memory cell and yBL and ySL for control logic circuits according to the Cartesian coordinates. The select transistors may connect zBL with yBL and zSL with ySL. The select transistors may include active area 1450, a source region having contact landing pad 1418, a drain region that connects horizontal control logic lines 1415 such as yBL and ySL, and select gate lines 1419. The contact landing pads 1418 may be aligned with the zBLs and zSLs 1410. The orientation of the select gate lines 1419 may be the same as the orientation of the wordline plane 1430. There would be many select gate lines 1419 within one wordline plane 1430. When a wordline plane 1430 is selected, only one of select gate lines 1419 may be turned on while the remaining select gate lines 1419 may be turned off. As a result, only those zBLs and zSLs of one row would be connected to yBLs and ySLs. For better understanding, FIG. 14C illustrates a layout view overlapping FIGS. 14A and 14B. For example, if a select gate line 1419b is selected, zBLs and zSLs of the second row of memory cell may be selected as illustrated in FIG. 14C.

In one embodiment of the present invention, the select gate transistor could be a horizontal channel transistor, for example, such as planar bulk transistor, fully-depleted SOI transistor, FinFET, or nanosheet transistor. In such a particular embodiment, in order to avoid obstruction of select gate lines 1419 or horizontal control lines 1415 due to the blockage caused by the connection of the contact landing pad 1418 and the vertical control lines 1410, the orientation of the channel length directions of the memory cell transistor and the select transistor could be tilted as shown in FIG. 14D. Such a tilt angle could be range between 15° and 75°, such as, for example about 30°, about 45°, or about 60°.

In another embodiment, the select gate transistor could be a vertical channel transistor, for example, such as a vertical nanowire transistor. The vertical nanowire transistor could be a conventional inversion mode transistor or junctionless mode transistor or a depletion mode transistor with a diode. As the miniaturization of the device and the technology node scaling continues, the layout efficiency needs to improve accordingly. The vertical channel transistor could be more compact than the horizontal channel transistor at the same technology node. A layout view of the select transistor array based on the vertical channel transistor is illustrated in FIG. 15A. Referring to FIG. 15A, the select transistor may consist of horizontal control logic lines 1515 such as yBL and ySL in the bottom, and select gate lines 1519 in the middle, and the contact landing pad 1518 in the top. The contact landing pads 1518 may be aligned with the zBLs and zSLs 1410.

For a better view, FIG. 15B illustrates a layout view overlapping the layout of 3D memory cell array in FIG. 14A and layout of select gate transistor array based on the vertical nanowire transistor shown in 15A. A magnified view of the vertical channel transistor connected with one zBL or zSL is shown in FIG. 15C. A three-dimensional bird-eye's view of FIG. 15B is shown in FIG. 15D. The select gate line 1519 could be a gate of the vertical nanowire transistor. The gate 1519 could be fully surrounding the nanowire channel 1520, forming gate-all-around. The horizontal control logic lines 1515 such as yBL and ySL could be a source region of the vertical nanowire transistor. The diameter of vertical nanowire 1520 could be substantially smaller than the diameter of the vertical control lines 1410 such as zBL or zS. The horizontal control logic lines 1515 are connected with the bottom of the nanowire channels 1520. The yBL and ySL could be heavily doped silicon regions, which could be a portion of the silicon wafer, thus also single or monocrystalline in nature. Alternatively, the yBL and ySL could be a metal line and the source regions could be separately formed above the metal line and underneath the bottom portion of the nanowire channel 5120. The contact landing pads 1518 could be formed above the drain region of the nanowire channel 5120. The contact landing pads could be formed during its metallization process. The contact landing pad 1518 could be one-to-one connected to the vertical control lines 1410 such as zBL or zSL.

The select transistors could be simultaneously fabricated with the core and peripheral control logic circuits. As a result, the channel material of the select transistor could be single crystal or monocrystalline silicon. Alternatively, the select transistor could be separately fabricated and overlaid on top of the core and peripheral control logic. Then, the select transistor could be built on its own single-crystalline semiconductor substrate and transferred onto the peripheral control logic. Alternatively, the select transistor could be sequentially built on the peripheral control logic and the nanowire channel material could include polycrystalline silicon.

Additional inventive embodiments presented are methods of forming control lines which support a specific 3D NOR memory cell access without using a select-transistor. In one embodiment, a control line structure of a 3D NOR architecture uses a way that one Word Line (“WL”) controls one vertical control line such as a SL and a BL which thus provides the selection of only one 3D NOR memory cell. As a result, a random access of a 3D NOR memory could be possible. While there could be various variations in arrangement of the SL and BL, the present embodiment could be applied to an arbitrary arrangement of SL and BL. Vertical control lines such as source and drain pillars of a 3D memory cell would be called zCL and horizontal control line connected to zCL could be called yCL according to their directionality. For better understanding, please see the terms ‘row’ and ‘column’ as indicated in the specification section describing FIG. 16A.

[one WL for one yCL] In one embodiment for random access by using no select gate, as shown in FIG. 16A, one WL controls only one row of zCL. Each WL 1630a, 1630b, 1630c, and 1630d controls only first, second, third, and fourth row of zCLs 1610, respectively. yCL 1615 connection to zCL would be made through contact landing pad 1618. Each yCL 1615a, 1615b, 1615c, . . . and 1615f connects only first, second, third, . . . and 6^{th} column of zCLs 1610, respectively. As a result, one arbitrary set of yCL and one WL would select only one 3D NOR memory cell. The structure shown in FIG. 16A would be simple. The tradeoff is that this practice requires separation space between every WLs, which would reduce area efficiency. In addition, the width of the WL for the staircase contact could be tight.

[one WL for two rows by odd-even yCL interleaving] In another embodiment for random access by not using a select gate, one WL 1630 controls two rows of zCLs 1610 as shown in FIG. 16B or FIG. 16C. Compared to FIG. 16A, total area for the separation space between every WL 1360 could be halved and width of WL could be widened for better staircase contact margin in FIG. 16B and FIG. 16C. In the sense that one WL controls more than two rows of zCLs, a WL could be called a WL plane. WL plane 1630a controls first and second row of zCLs 1610 and WL plane 1630b controls third and fourth row of zCLs 1610. yCL 1615 connection to zCL could be made through contact landing pad 1618. The random memory cell selectivity could be made by interleaving connection of yCL to zCL. For example, as shown in FIG. 16B, each yCL in odd column such as 1615ao, 1615bo, 1615co, . . . and 1615fo connects first row of zCL controlled by WL plane 1630a and the third row of zCL controlled by another WL plane 1630b. Each yCL in even column such as 1615ae, 1615be, 1615ce, . . . and 1615fe connects second row of zCL controlled by WL plane 1630a and the fourth row of zCL controlled by another WL plane 1630b. In order for such interleaving connection of yCL to zCL to be possible, there should be an offset zCLs in first/third rows and zCL in second and fourth rows as shown in supporting top layout view 1690. As a result, one arbitrary set of yCL and one WL would select only one 3D NOR memory cell. In this embodiment, the number of yCLs would be doubled compared to FIG. 16A. Then, the density of CL could be a limiting factor as the miniaturization of 3D NOR memory cells and arrays continue.

[one WL for two rows by top-bottom yCL interleaving] In another embodiment to enable random access by not using a select gate, similar to FIG. 16B, one WL 1630 controls two rows of zCLs 1610 as shown in FIG. 16C but the density requirement for yCL is halved by placing them on top and bottom of 3D NOR cells. WL plane 1630a controls first and second row of zCLs 1610 and WL plane 1630b controls third and fourth row of zCLs 1610. The random memory cell selectivity could be made by interleaving connections of yCL to zCL. yCL 1615 connection to zCL could be made through contact landing pad 1618 or yCL 1615 connection to zCL could be deliberately skipped by missing contact landing pad 1618. Therefore, the staggering or offsetting zCLs of some rows against other rows would not be required. For example, as shown in FIG. 16C, each yCL on top of 3D NOR cell such as 1615Ta, 1615Tb, 1615Tc, . . . and 1615Tf connects first row of zCL controlled by WL plane 1630a and the third row of zCL controlled by another WL plane 1630b. Each yCL in bottom of 3D NOR cell such as 1615Ba, 1615Bb, 1615Bc, . . . and 1615Bf connects second row of zCL controlled by WL plane 1630a and the fourth row of zCL controlled by another WL plane 1630b. As a result, one arbitrary set of yCL and one WL would select only one 3D NOR memory cell.

[one WL for four rows] In another embodiment to enable random access by not using a select gate, one WL 1630 controls four rows of zCLs 1610 as shown in FIG. 16D. WL plane 1630 controls first, second, third and fourth row of zCLs 1610. By combining the concept explained through FIGS. 16B and 16C such as staggering/offsetting offsetting zCL and using dual sided (top and bottom) yCL, the random memory cell selectivity could be achieved. The interleaving of yCL could be attained by connecting first, second, third, and fourth row of zCL 1610 with odd yCL on top of 3D NOR cell 1615To, even yCL on top of 3D NOR cell 1615Te, odd yCL on bottom of 3D NOR cell 1615Bo, and even yCL on bottom of 3D NOR cell 1615Be, respectively. As a result, one arbitrary set of yCL and one WL would select only one 3D NOR memory cell.

[interdigitated WL plane] In another embodiment which enables random access by not using a select gate, one WL 1630 controls two rows of zCLs 1610 as shown in FIG. 16E. However, compared to FIG. 16B and FIG. 16C, the width of WL plane could be widened for even better staircase contact margin in FIG. 16B and FIG. 16C. Despite the one WL 1630 controlling two rows of zCL, the width of the WL plane could be that of a WL plane covering three rows of zCL, which could be attained by at least, for example, an inter-digitated shape of the WL. WL plane 1630a controls first and third row of zCLs 1610 and WL plane 1630b controls second and fourth row of zCLs 1610. Interleaving yCL could be made by odd-even yCL connections of staggered row arrangement as explained in FIG. 16B. As illustrated by FIG. 16E, the random memory cell selectivity could be made by interleaving connections of yCL to zCL. For example, each yCL in odd columns such as 1615ao, 1615bo, 1615co, . . . and 1615fo connects first row of zCL controlled by WL plane 1630a and the second row of zCL controlled by another WL plane 1630b. Each yCL in even column such as 1615ae, 1615be, 1615ce, . . . and 1615fe connects third row of zCL controlled by WL plane 1630a and the fourth row of zCL controlled by another WL plane 1630b. Alternatively, the yCL interleaving could be attained by a top-bottom yCL connection (not drawn) as explained in FIG. 16C. A supporting top layout view of FIG. 16E is shown in FIG. 16F. While the WL staircase contact could be made on one side of 3D NOR cell array, the present embodiment would use left and right sides of staircase contacts 1640a, 1640b for leveraging the wide width of the staircase contact pad.

In an alternative embodiment, a body contacted 3D NOR-P structure is described which would allow faster operation speeds. The body contact herein could be also referred to as a back-gate, substrate, or channel contact.

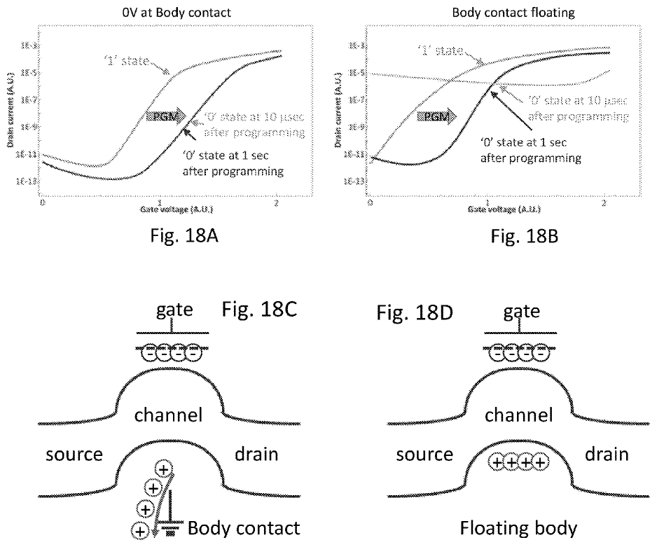

A technology CAD simulation is conducted to explain the benefit of a body-contacted memory cell transistor structure in terms of access speed. Gate-voltage versus drain-current characteristics for logic ‘0’ and logic ‘1’ states are shown FIG. 18A-18D. Logic ‘1’ state is low threshold voltage state where the charge storage (trapping) layer stores a substantially lower electron density. Logic ‘0’ state is high threshold voltage state where the charge storage (trapping) layer retains substantially large electron density. A programming operation is conducted to change the logic ‘1’ to logic ‘0’ state by storing electrons in the charge storage layer. The programming mechanism could be, for example, hot-carrier injection by impact ionization or Schottky tunneling. The results of FIG. 18A and FIG. 18B are from the memory cell transistor with and without a body contact, respectively. During the operation, the body contact would be, but not limited to, grounded. The gate-voltage versus the drain-current characteristics are read at two times after the programming operation: after waiting 10 micro-second (usec) and after waiting 1 second(s). As shown in FIG. 18A, the logic ‘0’ characteristics of the body contacted device are normal and identical for both 1 s as well as 10 μs. However, in the floating body device as shown in FIG. 18B, the drain-current for logic ‘0’ waiting for 10 μs shows an abnormal high for various gate voltages. In other words, the memory cell transistor stays turned on even when the gate voltage is biased at about 0 V to turn the cell off. The normal device characteristic for the logic ‘0’ state would be obtained after waiting a substantially long time, for example, such as about 1 sec. These phenomena suggest that, if the memory cell transistor includes a floating body, the user would be forced to wait for a longer time, ‘dead-time’, after a programming operation until the device becomes stabilized and could be properly read.

FIG. 18C and FIG. 18D show energy band diagrams along the source-channel-drain direction immediately after the programming operation in order to explain the mechanism of the ‘dead-time’. The programming operation involves a formation of hot carrier generation. The hot carrier generation creates an electron-hole pair. The program voltage is set to deform the energy band in a favorable way for the electrons to be attracted towards the charge storage layer. However, the holes are repelled toward the channel region and accumulate over time for a structure without body contact. As shown in FIG. 18C, if the memory cell transistor has its body contact, the generated holes would escape due to the zero or slightly negative voltage applied to the body contact. Therefore, no ‘dead-time’ would be suffered, which may be highly preferred for fast speed operation. However, as shown in FIG. 18D, if the memory cell has a floating body, the generated holes are accumulated and as a result, turn-on a parasitic bipolar transistor due to the source as an emitter, the channel as a base, and the drain as a collector, which results in a large off-state current. Such ‘dead-time’ elapses until the excess of holes naturally recombine, which could end-up limiting high speed operation of the memory cell.

In another embodiment, a method to reduce the ‘dead-time’ in a floating body memory cell is presented. As seen earlier, the dead-time is related to the lifetime of holes. Reducing carrier lifetime could reduce the dead-time. In order to reduce the carrier lifetime, a recombination center could be introduced in the channel region. The recombination center could be crystalline defects or a metallic center lodged in the crystal matrix. In one embodiment, an ion implantation using elements, for example, such as germanium or silicon could be applied to the cell channel, which creates the recombination centers. In another embodiment, a metallic contamination could be deliberatively introduced in the channel region. In particular, the use of metallic source and drain or Schottky barrier source and drain structure may automatically introduce the metallic center as recombination center for the excess carriers in the floating body.

In another embodiment, a two-step programming operation method to reduce a dead-time in a floating body cell could be used. The two-step programming operation may be consist of a programming voltage & time set for hot-carrier generation and charge storage, followed by a cleaning voltage & time set to actively remove the excess holes in the floating body. In one embodiment, a negative bitline voltage pulse, for example, such as about −0.6V or about −1.2V could be applied immediately after the programming voltage pulse (a ‘cleaning’ voltage & time). The negative bitline pulse may actively sweep out the excess holes in the floating body. As a result, the dead-time could be eliminated in the floating body type 3D NOR-P memory devices by using a programming operation method adjustment.

In another embodiment, a 3D NOR-P multilayered memory stack having a shared body contact is presented. In the prior art, two types of 3D NOR-P structures were presented. As illustrated in FIG. 17A, multilayered memory stacks are sharing one macaroni channel. The macaroni channel would have an empty or dielectric filled core region with a tubular shell serving as the memory cell channel. The tubular shell could have a thickness ranging from, for example, about 5 nm to about 50 nm. In one embodiment, the top portion of shell region could be extended above the top of the upper most gate as drawn in FIG. 17A or below the bottom of the bottom-most gate (not drawn). The macaroni extension region could be highly doped and a body contact could be made in the extension region. Another option of a 3D NOR-P structure in the art may have an individually isolated donut channel per memory cell transistor as illustrated in FIG. 17B. The donut channel could have an empty or a dielectric filled core region with a ring-shaped shell serving as the memory cell channel. In one embodiment, a donut padding pillar may added across the core regions of the many layers of donut channels, as illustrated in FIG. 17B. The donut padding pillar is extended above the top of the upper most gate as drawn in FIG. 17B or below the bottom of the bottom most gate (not drawn). The donut padding pillar could be moderately doped in order to suppress the subthreshold leakage current flowing from source to drain through the bulk region of the donut padding pillar. The extension region of the donut padding pillar could be heavily doped and the body contact could be made. In another embodiment, a 3D NOR-P structure with a donut padding pillar may be further modified to suppress the subthreshold leakage current flowing from source to drain through the bulk region of the donut padding pillar. As illustrated in FIG. 17C, a dielectric which electrically isolates the donut padding pillar from the source and the drain is added to at least one side or both sides of the source and the drain while the donut padding pillar is in contact with the inner surface of donut shells in their center region.

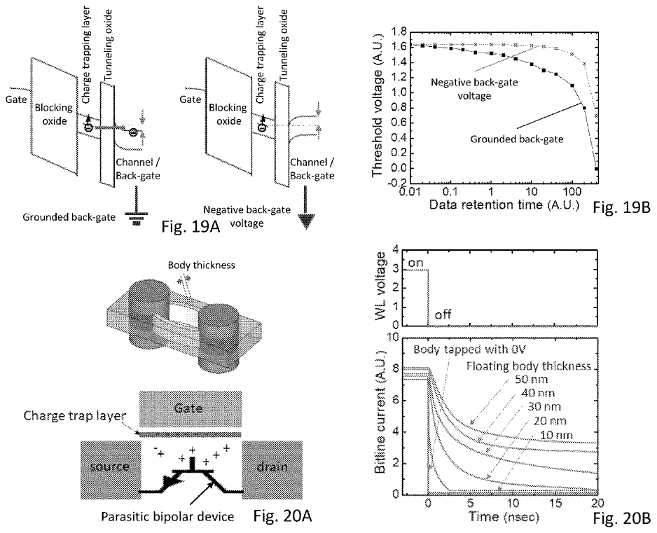

In one embodiment, another advantage of the 3D NOR-P structure having a back-gate element is data retention time improvement. In the 3D NOR-P structure, particularly with a substantially thin tunneling oxide such as a few atomic thick, the advantage of fast programming and erasing operation trades off with the data retention time. More specifically, the data retention time for the programmed state where the electrons are trapped in the charge trapping layer could be improved. The loss of storage charges could be a combination of thermal excitation over the energy barrier height and direct and indirect tunneling through tunneling oxide. For the substantially thin tunneling oxide, the retention time degradation due to tunneling could be a major mechanism for reduced data retention. FIG. 19A shows an energy band diagram of the programmed state with a back gate. When the back-gate is grounded, the energy level of the conduction band of channel could be lower than the energy level of the charge trap site as shown in the left panel of FIG. 19A. Therefore, the electrons in the charge trap site may find a more favorable level in the channel, which could facilitate the tunneling. When a slightly negative back-gate voltage is applied to the channel through the back-gate contact, the energy band of the channel could be slightly bended upward as shown in right panel of FIG. 19A. Then, the energy level of the charge trap site could be lower than the energy level of the conduction band of the channel. Therefore, the charge would favorably remain in the charge trapping site. As a result, the data retention time could be improved by gently applying a negative voltage to the back-gate. The negative voltage to the back-gate could be, for example, such as −0.2V or −0.3V, −0.5V or −1.0V or even more negative, depending on a specific design of the memory cell and application. It should be noted that the negative voltage to the back-gate for the retention time improvement need to be not too high to avoid a disturb to cells with the erased state. FIG. 20B shows a simulation based on the device physics. The extension of the data retention time of the programmed state may be verified when a negative back-gate voltage is applied.

In one embodiment, a 3D NOR-P device having a macaroni or donut channel without body tap could be engineered to further minimize the ‘deadtime’ by using body thickness. The device without body tap could be referred to as a floating body. FIG. 20A illustrates a unit memory cell of 3D NOR-P and its planar equivalent diagram. The charge dynamics involved with the floating body in a 3D NOR-P device could result in the formation of parasitic bipolar devices formed by source, channel, and drain as illustrated in FIG. 20A. The parasitic bipolar device stays quiet in stand-by. However, when a relatively large voltage pulse is applied to the terminals, such as a programming operation, excess of majority charges could be built up in the floating body, activating the parasitic bipolar device. For example, the programming operation in 3D NOR-P associates with a generation of energetic electrons through impact ionization or Schottky injection. This generation of electrons, which are paired with the generation of holes, are named electron-hole pairs. The generated electrons could be trapped in the charge trap layer and swept away to a positive voltage applied to source or drain junction.

However, the generated holes could stay in the floating body because pn junction potential barriers are inherent in the source and drain junctions, as illustrated in FIG. 18D. Therefore, the excess holes (positive charges) in the floating body come to be a base current of the parasitic bipolar device. Even when the gate voltage is biased in a hold condition to turn off the memory cell transistor, the excess holes could stay and partially turn on the parasitic bipolar device. As a result, until those excess holes naturally dissipate through recombination, the memory cell device could be partially turned on. As a result, once the excess holes exist in the floating body, it takes some time to fully turn off the memory device, which could interfere with the next operation. The transient bit-line current characteristics after programming pulse are simulated and the results are illustrated in FIG. 20B. For a memory cell device with body taps biased at OV, the device is turned off spontaneously. However, memory cell devices with a floating body could show a slow response for the turning off operation. The transient characteristics of the turn-off are tested for various floating body thicknesses. The device with a body thickness close to about 50 nm could reach a few seconds to fully turn off. However, as the body thickness becomes thinner, the time to off or settle time is dramatically shortened. In the case of the body thickness below about 20 nm, the settle time becomes a few ns. Such phenomena could be explained by the fact that the number of excess holes in the floating body is governed and limited by the body thickness. Also, the thinner body thickness can push those excess holes near S/D junctions, thus accelerating the recombination rate. In one embodiment, the thickness of a floating body-based 3D NOR-P could be designed to have a body thickness thinner than about 20 nm.

According to one embodiment, a process step of Metal Induced Lateral Crystallization (“MILC”) of the polysilicon channel could be applied in a 3D NOR-P process. In the previous art in U.S. Pat. No. 11,069,697 B1, incorporated herein by reference, the MILC process is applied through the metalized source/drain after forming the charge trapping layer. However, while the re-crystallization process is being conducted, the gate oxide interface quality could be worsened and the cell-to-cell variability could be exacerbated. In this particular embodiment, the MILC process for the polycrystalline channel could be conducted before the charge trapping layer process step. Furthermore, the gate of the memory cell transistor or wordline could be a replacement metal gate. The MILC process is presented in a paper by Lee, Seok-Woon, and Seung-Ki Joo. “Low temperature poly-Si thin-film transistor fabrication by metal-induced lateral crystallization.” IEEE Electron Device Letters 17.4 (1996): 160-162, incorporated herein by reference. In some literature, the MILC process is also referred as Metal Induced reCrystallization (“MIC”) as the recrystallization direction is not always lateral. The similar recrystallization process is applied in polysilicon channel 3D NAND structures as presented in U.S. Pat. No. 8,445,347B2, incorporated herein by reference. A time required for the MIC process in a 3D NAND channel usually takes a few hours as the length of the channel is often greater than 5 μm. However, a time required for MIC process for 3D NOR-P channel could be less than one hour as the length of the channel could not be less than 0.2 pm.

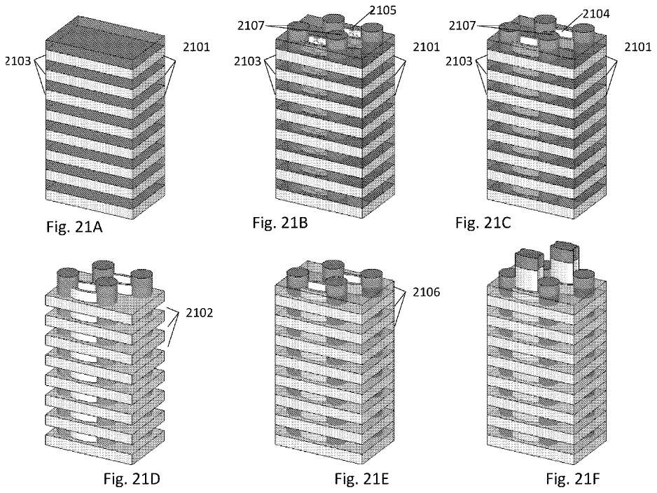

A process step for MIC in 3D NOR-P is presented in reference to FIG. 21. As shown in FIG. 21A, silicon nitride (SiN) 2101 and silicon dioxide (SiO2) 2103 layers are alternatively stacked. The silicon dioxide 2103 layer herein could be an inter-wordline dielectric layer and the silicon nitride layer 2101 could serve as a sacrificial layer to be later replaced by the wordline material.

FIG. 21B illustrates the polysilicon channel 2105 and the metallic source/drain regions 2107 being formed according to a similar process as was explained in respect to at least FIG. 1 of U.S. Pat. No. 11,069,697, incorporated herein by reference. The polysilicon channel 2105 could also be an amorphous phase channel, if appropriate. The polysilicon channel 2105 could be a macaroni type or a donut type. The metallic source/drain 2107 could form a Schottky barrier with polysilicon channel 2105. Both source/drain 2107 could be metallic. Alternatively, at least one side from the source or drain 2105 could be metallic while another side from the source or drain 2105 could degenerately doped polysilicon or other type of heavily doped semiconductor.

FIG. 21C illustrates the structure of FIG. 21B after the MIC process is conducted. After the MIC process, the crystalline phase of as-deposited polysilicon channel 2105 could be substantially improved and turned into recrystallized silicon channel 2104. The result of MIC could be an increase in the grain size of the polycrystalline channel, enhancement in carrier mobility, which could result in a reduction in trap-assisted leakage current.

FIG. 21D illustrates the structure of FIG. 21C after the removal of the sacrificial silicon nitride (SiN) layer 2101 through a slit (not drawn). The slit could be a SiN/SiO2 etched out linear trench formed for segmentation of a smaller block. The portion in which the sacrificial silicon nitride (SiN) layer 2101 has been removed could become empty space 2102.

FIG. 21E illustrates the structure of FIG. 21D after having the charge trapping layer such as oxide/nitride/oxide stack or nitride/oxide stack be conformally deposited, followed by filling the remaining space with wordline 2106, such as heavily doped polysilicon or tungsten. Optionally, the back-gate process could follow according to the benefit explained in FIG. 17-20 herein.

In one embodiment, the 3D NOR-P memory array structure uses the metal-semiconductor junction for the source and the drain of the memory cell transistor. In ordinary memory transistors, a heavily doped silicon containing a layer such as phosphorous or arsenic doped silicon containing layer is used for the source and drain. However, a high temperature process after heavily doped silicon containing layer such as annealing could result in the diffusion of dopants into the silicon channel along the channel length direction. Consequently, the device could form a gradual junction profile and shorten the effective channel length. This fact could cause short channel effects such as high leakage current and thus may severely limit the miniaturization of the memory cell transistor. According to one embodiment, the metal-silicon junction or Schottky junction could be used for the source and the drain of the memory array structure. The suppression of the leakage current and superiority in scaling of Schottky barrier devices have been demonstrated such as in, Calvet, L. E., et al. “Suppression of leakage current in Schottky barrier metal-oxide semiconductor field-effect transistors.” Journal of applied physics 91.2 (2002): 757-759; Calvet, L. E., et al. “Subthreshold and scaling of PtSi Schottky barrier MOSFETs.” Superlattices and Microstructures 28.5-6 (2000): 501-50; and Huang, Chung-Kuang, Wei E. Zhang, and C. H. Yang titled “Two-dimensional numerical simulation of Schottky barrier MOSFET with channel length to 10 nm.” IEEE Transactions on Electron Devices 45.4 (1998): 842-848; which in their entirety are all incorporated herein by reference.

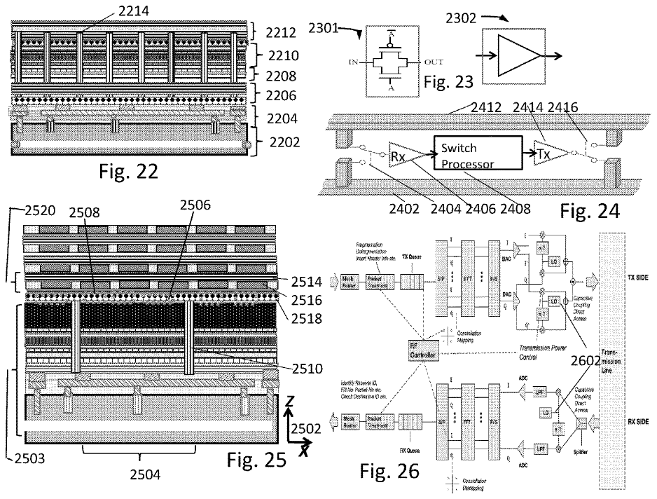

FIG. 22 is an alternative structure to the one presented in FIG. 16C of PCT/US21/44110, the entire contents which are incorporated herein by reference. FIG. 22 illustrates a substrate with a built-in heat removal level 2202 overlaid with power delivery level 2204 overlaid with X-Y connectivity level 2206. This could be considered as a 3D device level, for example, such as an advanced interposer, on top of which various compute devices could be integrated as dies or as wafers. These foundations could be made generic according to a specified standard or custom spec to support a specific 3D system or a group of specific 3D systems and/or devices. Vertical buses 2214 could connect the foundation levels to a level of processors 2208 with their memory stack 2210. An additional X-Y connectivity level and input/output level 2212 could be placed on top. The various levels could be stacked using level transfer techniques and bonding such as hybrid bonding as presented in more detail in at least the incorporated by reference arts.

The heat removal level 2202 overlaid with power delivery level 2204 overlaid with X-Y connectivity level 2206 as an interposer could be constructed using panel technology as is illustrated in FIG. 23 and wafer, die, reticle of device level could be boded on top. These foundation levels may be built with a relatively course lithography such as been used for display panel or photo voltaic panels. The device level which could include processor and memory could be constructed with advanced lithography which is in general available for wafer type device processing. The driver for the X-Y connectivity and the transmit receive and control circuit could be done with fine lithography process such as the processors and the memory while the X-Y wave guides or the X-Y transmission lime connectivity could be done with the course lithography.

Herein the term hybrid bonding is often used and means bonding which includes oxide to oxide and metal to metal bonding zones. In many cases while the term hybrid bonding is used it reflects a broader bonding options such as metal to metal and/or oxide to oxide. The selection of the specific bonding technology could be determined by an artisan in the art to match the preferred engineering choice for the specific use case.

The X-Y interconnect could be constructed with any of the techniques presented herein or in the incorporated by reference art. Packet based communication protocol is a good way to manage a large amount of message sources and destinations. And as such the use of Internet Protocol (“IP”) could be an attractive option as it becomes one of the most popular industry standard use very large software and hardware technologies been widely available following the internet being very broadly used.

The X-Y interconnect technologies were presented such as in reference to at least FIG. 33A to FIG. 43 E of U.S. Pat. No. 11,121,121, incorporated herein by reference, in reference to at least FIG. 6 to FIG. 8B and FIG. 21A to FIG. 27B of PCT application WO 2019/060798, incorporated herein by reference, and in reference to at least FIG. 15A-15W of PCT application PCT/US2021/044110, incorporated herein by reference. These X-Y interconnect technologies could leverage technologies, for example, such as, optical interconnects, RF interconnects, and conventional wired interconnects.

An additional option is to leverage technology commonly called in the art as SerDes technology. These circuits are used for data transfer between devices and usually include circuits to take parallel bus data and serializing it at the transmitter end and de-serialize the data stream at the receiver end. In many cases the clock information is coded into the data stream and then recovered at the receiving end saving the extra wires to transmit the clock signal and reduce the risk of signal skew due to un-balanced wires.

In many cases, SerDes is used with differential signaling and may include advanced signaling, for example, such as, Pulse Amplitude Modulation (“PAM”), to obtain more efficient data transfer. In some references, these types of data transfer are called base band while RF modulation is used for higher frequencies. In many cases the wires used for these SerDes are design like transmission lines. In general SerDes is used to connect individual devices, for example, such as one or more HBM memory to one or more processor devices. A processor device in at least this context may be a memory or set of memories configured and/or programmed to mimic and act like a processor. Using SerDes within a 3D system for X-Y connectivity could be an effective solution for long lines such as for X-Y connectivity for distances greater than 5 mm and in some cases lines longer than 40 mm, 100 mm, 200 mm or even longer lines. Many SerDes designs are for point to point connectivity but some designs support multi-drops connectivity such as been presented in at least a paper by Ito, Hiroyuki, et al. “A bidirectional-and multi-drop-transmission-line interconnect for multipoint-to-multipoint on-chip communications.” IEEE Journal of Solid-State Circuits 43.4 (2008): 1020-1029; by Sacco, Elisa, et al. “A 5 Gb/s 7.1 fJ/b/mm 8×multi-drop on-chip 10 mm data link in 14 nm FinFET CMOS SOI at 0.5 V.” 2017 Symposium on VLSI Circuits. IEEE, 2017; and by Lu, Lejie, et al. “Concurrent Multipoint-to-Multipoint Communication on Interposer Channels.” 2019 IEEE/ACM International Symposium on Low Power Electronics and Design (ISLPED). IEEE, 2019, the entire contents all of the preceding are incorporated herein by reference. A combination of RF connectivity with base-band connectivity was presented in a work by Wang, Xiaoyan, “Three-Dimensional (3D) Memory I/O Interface Design Using Quad-Band Interconnect (QBI) And Eight-Level Pulse Amplitude Modulation (8-PAM).” (2021), incorporated herein by reference. Additional multi-drop base band interconnect technology is detailed in at least a paper by Wary, Nijwm, Antroy Roy Chowdhury, and Pradip Mandal. “Hybrid bidirectional transceiver for multipoint-to-multipoint signaling across on-chip global interconnects.” IET Circuits, Devices & Systems 14.6 (2020): 780-787, incorporated herein by reference, utilizing a hybrid of current mode and voltage mode receivers for improved efficiency.

SerDes designs for point to point are common in the industry and many of these designs could be a good fit for the 3D System X-Y connectivity included at least herein. Some designs could also support some multi drop connectivity. A 3D System could include various lengths of data channels and various types and designs of transmission lines. The engineering of a specific X-Y connectivity may need to be fitted to the specific 3D System application. These could leverage such SerDes work published by at least Seual, Yoav, et al. “A 1.41 pJ/b 224 Gb/s PAM-4 SerDes Receiver with 31 dB Loss Compensation.” 2022 IEEE International Soli-State Circuits Conference (ISSCC). Vol. 65. IEEE, 2022; by Guo, Z., et al. “A 112.5 Gb/s ADC-DSP-Based PAM-4 Long-Reach Transceiver with >50 dB Channel Loss in 5 nm FinFET.” 2022 IEEE International Solid-State Circuits Conference (ISSCC). Vol. 65. IEEE, 2022; by Ye, Bingyi, et al. “A 2.29 pJ/b 112 Gb/s Wireline Transceiver with RX 4-Tap FFE for Medium-Reach Applications in 28 nm CMOS.” 2022 IEEE International Solid-State Circuits Conference (ISSCC). Vol. 65. IEEE, 2022; by Kocaman, Namik, et al. “An 182 mW 1-60 Gb/s Configurable PAM-4/NRZ Transceiver for Large Scale ASIC Integration in 7 nm FinFET Technology.” 2022 IEEE International Solid-State Circuits Conference (ISSCC). Vol. 65. IEEE, 2022; and by Chen, Run, et al. “A 6.5-to-10 GHz IEEE 802.15. 4/4z-Compliant 1T3R UWB Transceiver.” 2022 IEEE International Solid-State Circuits Conference (ISSCC). Vol. 65. IEEE, 2022, the entire contents of all of the forgoing are incorporated herein by reference.

SerDes circuits are broadly used in the industry and possess a wide choice of circuits and support infrastructure such as software, simulation and testing and thus are available to assist integration of such circuits into the 3D system X-Y connectivity. Typical SerDes circuits includes elements such clock coding, data coding, differential transmitter and receiver design, clock reconstruction and synchronization, serializing and de-serializing. The use of such connectivity within a 3D system could open up the option to use some of these circuits rather than all of them, where in 3D system connectivity other tradeoffs could become a better option. For example it might be desired to transmit the clock signal along with the data and to save some of the circuits associated with clock coding and clock recovery. In a 3D system the cost per wire could be much lower than in device to device connectivity. In a 3D system making a symmetric bus of eight lines that are very similar and accordingly with relatively small signal skew is not too difficult and accordingly the need to serialize and de-serialize could be reduced. Such multi-wiring connectivity has been presented by at least Stojčev, Mile, and Bojan Dimitrijević. “On-and Off-chip Signaling and Synchronization Methods in Electrical Interconnects.” International Journal of Electrical Engineering and Computing 5.2 (2021): 59-68, incorporated herein by reference.

In the inventive 3D System, the X-Y interconnect fabric could extend horizontally in both or either X and Y directions for a wide range of distances; for example, such as 10 mm, 50 mm, 250 mm, or even longer. The connectivity needs could be for a very large array of processors such as 50×50, 250×250, 1250×1250 or even larger. Such very large array and the potential need to transfer data from any point within the array to any point within the array makes the X-Y connectivity a challenging data routing problem. The X-Y connectivity could include short connections such as 2-10 mm long, medium connections such as 10-50 mm long, and long connections such as greater than 50 mm long, these connections could be structured as X direction connections and Y direction connections. In at least the application PCT/US2021/044110, incorporated herein by reference, such X-Y connectivity is presented in reference to its FIG. 15A-15W with a few options for connecting segments of connections in reference at least to its FIG. 15J. Such segment connections could be used for data transfer using a base band such as with SerDes as presented herein FIG. 23 and FIG. 24. FIG. 23 illustrates a connection switch 2301 and a signal amplifying element 2302. The data transfer may be with differential signaling so that these elements could be used for each of the line pair. For simplicity it is shown here only for one of the lines.

FIG. 24 illustrates an advanced connection which could be considered as a data switch. One of the signal segments 2412 could be connected through a switch 2404 to a receiver logic 2406 which will be connected to the switch processor 2408. The switch processor 2408 could include memory to store the data packet and to later transmit it using a transmitter circuit 2414 through a switch 2416 to the other signal segment 2402. Such is when the signal is going from the segment 2412 to the segment 2402, if the signal direction is from 2402 to 2412 then the switches 2404 and 2416 are switched to the other polarity.

In the inventive 3D System, the routing control could be managed to support the 3D System operation for a specific task. The routing control could be done using conventional wire connections or using a broadcast option if it is available as presented in the incorporated by reference art. One of the design objectives is to improve power efficiency of the system so that the massive data transfer between the processors on the 3D System may be done with reduced power consumption. Packet switching and the central connectivity control could help achieve this objective and goal. The system could incorporate the connectivity control with the overall software control to control the data transfer operation with the data processing operation.

The X-Y connectivity fabric could be structured so that multiple connectivity lines such as wave guides or transmission lines (“TL”) to run on top of or below the logic fabric-the array of processors. Each of the processors could be provided with access to multiple TLs including TLs that are short, medium, and long oriented in X direction and others that are oriented in Y direction. Some of these TLs could be connected with transmit and receive circuits while other could be with receive only or transmit only, enabling asymmetric capabilities between upload-transmit, and down load-receive. In some cases there might be a need for higher data rate to be received, hence more receive circuits than transmit circuits supporting higher download capability than upload capability.

FIG. 25 is an X-Z 2502 cut view illustration of 3D system section having pairs multiple pairs 2520 of X-Y connectivity levels. It resembles at least FIG. 14A of application PCT/US2021/044110, incorporated herein by reference. The 3D System base fabric 2503 may include array of units 2504 each with its processor and memory stack and a vertical bus 2510 to connect the system functional levels. The X-Y communication circuit level 2518 could include one transmitter circuit 2506 and multiple receive circuits 2508. The TL could include pairs of X-Y connectivity level 2520 in which could include Y direction TLs 2516, and X direction TL 2514. These TL could be constructed as presented in application PCT/US2021/044110, incorporated herein by reference, in reference to its FIG. 15F. The TL could cross over a unit without connection to it or with connecting vias, not shown, to the underlying communication circuit.

In some cases some units could be designed so that their communication circuit(s) could be designed for base band communication while other units could communicate at a higher frequency rf band with the proper frequency modulation and or demodulation.

Using RF bands increases the utilization of the data channels—the TLs—and could help reduce the power needed for data transfer as it moves the data on an LC dominated lines rather than RC dominated lines. Using active multi-drops enable a flexible data routing fabric that could effectively support various use cases of the 3D System. A technology that supports multi-drop and multi frequency modulation is called Orthogonal Frequency Division Multiple Access (“OFDMA”) and is presented in a paper by Unlu, Eren, et al. “An OFDMA based RF interconnect for massive multi-core processors.” 2014 eighth IEEE/ACM international symposium on networks-on-chip (NoCS). IEEE, 2014; by Unlu, Eren, and Christophe Moy. “Reconfigurable traffic-aware radio interconnect for a 2048-core chip multiprocessor.” 2015 Euromicro Conference on Digital System Design. IEEE, 2015; by Unlu, Eren. Allocation dynamique de bande passante pour l'interconnexion RF d'un réseau sur puce. Diss. CentraleSupélec, 2016; by Unlu, Eren, et al. “Capacity Analysis of Radio Frequency Interconnect for Manycore Processor Chips.” Fifth International Conference on Telecommunications and Remote Sensing. Vol. 1. SCITEPRESS, 2016; and by Unlu, Eren, and Christophe Moy. “Bimodal packet aware scheduling for an OFDMA based on-chip RF interconnect.” Journal of Parallel and Distributed Computing 109 (2017): 15-28, all of the forgoing in their entirety are incorporated herein by reference. These data modulation techniques support flexible and adaptable data routing use with broadcast capability. And it does not require the implantation of redundant static components such as filters, mixers, etc. The generation and redistribution of orthogonal frequency channels is a digital procedure. Therefore, in this sense, it is intrinsically scalable in terms of footprint area and power, with ever increasing bandwidth for the future.

FIG. 26 is a schematic diagram of OFDMA circuits as presented in FIG. 3.10 at the Eren Unlu's Dissertation, incorporate herein by reference. As FIG. 26 illustrates, Local Oscillator (“LO”) 2602 could be used to up modulate the base band signal at the transmit side and then could be used to down modulate at the receive side. In a 3D System it could be effective to make this LO signal as a global signal to be broadcast over TL lines in X direction and in Y direction 2520 making it available to the various units' Switch Processors. Reducing the need for local oscillators and reducing the noise associated with the jitter between such local oscillators. One advantage of the 3D System fabric is the relatively high availability of TL resources as is illustrated in FIG. 25. The 3D System X-Y communication could be controlled for better system efficiency with the option to selectively feed one of the crossing TLs to the Transmit or Receive circuit under the central control instruction. Accordingly one communication circuit could support multiple TL resources. The access to the TL could utilize techniques presented in the incorporate by art reference, for example, such as direct access, capacitive coupling, γ/4 inductive coupling or transistor controlled, which could be simple and effective coupling technology. In a paper by Hamieh, Mohamad, et al. “A new interconnect method for radio frequency intra-chip communications using transistor-based distributed access.” Microwave and Optical Technology Letters 61.2 (2019): 297-302, incorporated herein by reference, in which it was shown that transistor controlled access could be the better access to TLs by the individual nodes.

OFDMA technology is a good fit for the 3D System X-Y connectivity for a multiple reasons such as: An efficient data transfer technology which could provide reduced power for the data transfer with a relatively short time delay. It utilizes primarily digital circuits which are compatible with the high circuit integration of the 3D System with the reduced need for discrete components such as resistors, capacitors, and inductors. It allows adaptive resource allocation which could allow the 3D System to allocate the connectivity resources to the specific computing task being processed by the 3D System. And as OFDMA use has accelerated in recent years for many wireless applications the availability of circuits and software support has been increased helping the engineering effort to integrate OFDMA in the 3D Systems.

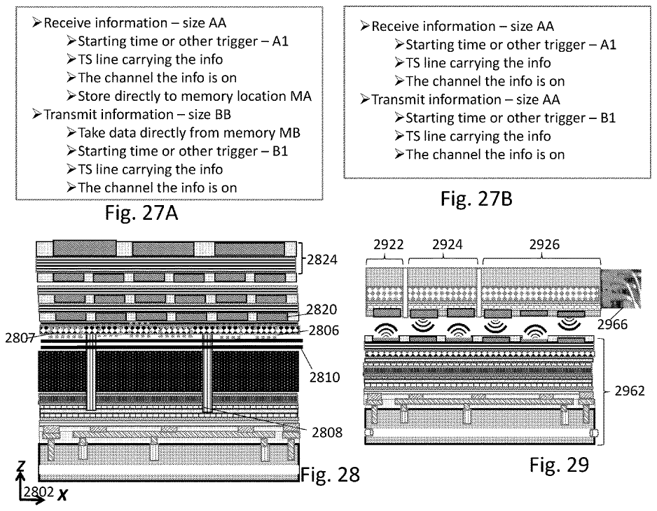

The 3D System could use a dynamic X-Y connectivity control. Such dynamic routing could be done per compute task to allow enhanced 3D System resource allocation supporting the specific computing task. The distribution of the routing control could be done with conventional X-Y metal connectivity or by utilizing a broadcast technique over the X-Y connectivity described herein. The broadcast could be performed using a special one-to-many connectivity such as with SWI or by utilizing the baseband for such. An additional option is to use the intrinsic broadcast capability of OFDMA. The X-Y routing assignment could be prepared ahead to be aligned with the compute resource allocation for the specific task and be provided to the 3D System. The computing task per specific unit could be assigned as a program assignment to the specific unit within the 3D System, as has been presented in reference to FIG. 3D and FIG. 3E herein. In a similar way the X-Y communication control could be provided to the 3D System to be distributed to all relevant communication processors. FIG. 27A illustrates an example for such a communication control instruction module. The instruction module could include the size of data to be received and a trigger or starting time to receive the information. It could also include which TS is designated to carry the information and which modulation channel the data is on for multiple access cases such in the case of FDM or OFDMA. The instruction module could also include similar information for data to be transmitted. As was presented in at least PCT/US2021/044110, incorporated herein by reference, in reference to its FIG. 15G-15I, the unit communication processor could have direct access to the unit memory stack. In such a case, the instruction could include the data location MA for the receive process, and the data location MB for the transmit process. The unit Communication Processor could have a simple exchange with unit Compute Processor such as new data size AA was just received and been stored at location MA and similar type of exchange for the data transmit process.

FIG. 27B illustrates an example for a communication control instruction module designated for the switch processors associated with the data transmission cycle, or as a full repeater for long traveling packet.

The 3D System size could be relatively large, for example, such as panel level or wafer level with X direction and Y direction sizes of 100 mm, 200 mm, 400 mm or even larger. The X-Y communication needs to manage short distance communication, such as 4 mm, to very long distances such as previously cited. The use of multi-tier TLs as discussed could be used to manage the X-Y communication for such a 3D System. An additional alternative is to use the flexibility of OFDMA to have a long distance target communication having an increased resource allocation to allow redundancy so that the same data is coded into multiple OFDMA bands to allow high error rate recovery at the receiving end. OFDMA adaptability and dynamic resource allocation flexibility could be used to compensate for the higher attenuation associate with transmitting a message over longer TL. The resource allocation could be doubled or quadrupled over the normal allocation as required by at least engineering considerations.

Additional techniques could be incorporated in OFDMA X-Y connectivity to better support long distance data transfer such as been presented in a paper by Sattar, Iqra, Muhammad Shahid, and Mohsin Khan. “A review of precoding based system to reduce PAPR in OFDMA.” Int J Multidiscip Sci Eng 6.2 (2015): 34-37; and Emarah, Elsayed Hassan Mahdy Ali, Mohamed El Tokhy, by Hany Kasban. “Development of signal recovery algorithm for overcoming PAPR in OFDMA communication system.” Arab Journal of Nuclear Sciences and Applications 55.1 (2022): 15-33; and by Jia, Jia, and Julian Meng. “A dual protection scheme for impulsive noise suppression in OFDM systems.” AEU-International Journal of Electronics and Communications 68.1 (2014): 51-58, all of the forgoing in their entirety are incorporated herein by reference.

Other forms of distributed X-Y communication control could be used including the use of packet switching in which a data packet includes the address they are targeting and the communication control processors could read these addresses and help direct the data to its address.

Data communication is common in many systems and data routing and control technologies used and those system such as Server Farm could be adapted and be used in such a 3D System.

In a paper by Tahanian, Esmaeel, et al. “Scalable thz network-on-chip architecture for multichip systems.” Journal of Computer Networks and Communications 2020 (2020), the entirety incorporated herein by reference, the use of a Parallel-Plate Waveguide (“PPW”) is proposed as an alternative to a wireless interconnect. The use of PPW confines the electromagnetic wave speeding thru the parallel-plate structure thus improving the power efficiency of electromagnetic wave transmission and improve data security by reducing the risk of the data being leaked out and detected by undesired entities. Integrating the proper PPW within the 3D System could be done using the level transfer technology. Such PPW could provide additional X-Y connectivity by using the effective one-to-many and broadcast capability. Such could be an alternative or a variation to the use of Surface Wave Interconnect (“SWI”) proposed in application PCT/US2021/044110, incorporated herein by reference. OFDMA could be used with PPW for the broad level connectivity and using TL with OFDMA could be added to provide a more targeted connectivity supporting a very parallel X-Y connectivity.

FIG. 28 is an X-Z 2802 cut view illustration of a 3D system section similar to FIG. 25 with the addition of Parallel-Plate Waveguide (“PPW”) 2810. A unit transmitter 2807 or receiver 2806 could have access to use the PPW if the message is to be broadcast or to a transmission line 2820 if the message is directed to limited number of units. The vertical connectivity bus 2806 could use one or more shielded vias to connect through the PPW. Alternatively 2810 could be a surface wave plate as presented in the paper by Karkar, Ammar, and Alex Yakovlev. “Leveraging Wire-Surface Wave Interconnects Architecture for one-to-many traffic in Network-on-chip”, incorporated herein by reference. Additionally the X-Y interconnect could include a hierarchy of TLs, for example, such as local, mid-range, and long range with a wider metal line/space pair as well as thicker conductors and insulators for the longer range TL 2824.

In application PCT/US2021/044110, incorporated herein by reference, in reference to at least its FIG. 16F, the use of wireless connectivity has been presented to support connecting the 3D System to an external system. Such a concept could be extended as is illustrated herein FIG. 29 showing use of wireless connectivity connected a 3D System 2962 to multiple other systems such as, data connectivity subsystem providing connectivity to other system via a fiber-optic connectivity 2966, and smaller 3D Systems 2922, 2924. These smaller 3D Systems 2922, 2924 could be an extension of the 3D System concept with an added dedicated function which might have very different form and function than the base 3D System 2962. These could also include ad hoc addition(s) of a dedicated smaller system for a temporary time to support a specific task execution.

Aaa

Aa

Aa

Aa

aa

Aa

In this document, the connection made between layers of, generally single crystal, transistors, which may be variously named for example as thermal contacts and vias, Through Layer Via (“TLV”), TSV (Through Silicon Via), may be made and include electrically and thermally conducting material or may be made and include an electrically non-conducting but thermally conducting material or materials. A device or method may include formation of both of these types of connections, or just one type. By varying the size, number, composition, placement, shape, or depth of these connection structures, the coefficient of thermal expansion exhibited by a layer or layers may be tailored to a desired value. For example, the coefficient of thermal expansion of the second layer of transistors may be tailored to substantially match the coefficient of thermal expansion of the first layer, or base layer of transistors, which may include its (first layer) interconnect layers.

It will also be appreciated by persons of ordinary skill in the art that the invention is not limited to what has been particularly shown and described hereinabove. For example, drawings or illustrations may not show n or p wells for clarity in illustration. Furthermore, transistor channels, if illustrated or discussed herein, may include doped semiconductors, but may instead include undoped semiconductor material. Further, any transferred layer or donor substrate or wafer preparation illustrated or discussed herein may include one or more undoped regions or layers of semiconductor material. Moreover, epitaxial regrow of source and drains may utilize processes such as liquid phase epitaxial regrowth or solid phase epitaxial regrowth, and may utilize flash or laser processes to freeze dopant profiles in place and may also permit non-equilibrium enhanced activation (superactivation). Further, transferred layer or layers may have regions of STI or other transistor elements within it or on it when transferred. Rather, the scope of the invention includes both combinations and sub-combinations of the various features described hereinabove as well as modifications and variations which would occur to such skilled persons upon reading the foregoing description. Thus the invention is to be limited only by the appended claims.

1-30. (canceled)

31. A 3D semiconductor device, the device comprising:
a first level comprising logic circuits;
a second level comprising a plurality of connectivity units,
wherein said first level is overlaid by said second level,
wherein each of said plurality of connectivity units comprises at least one receiver circuit; and
horizontally oriented transmission lines,
wherein at least one of said plurality of connectivity units comprises an Orthogonal Frequency Division Multiple Access (“OFDMA”) modulation circuit.

32. The 3D semiconductor device according to claim 1,
wherein said plurality of connectivity units comprise at least one transmitter circuit and a plurality of independently operated receiver circuits.

33. The 3D semiconductor device according to claim 1,
wherein at least one of said horizontally oriented transmission lines is connected so to distribute a clock signal.

34. The 3D semiconductor device according to claim 1,
wherein at least two of said plurality of connectivity units share a single local oscillator.

35. The 3D semiconductor device according to claim 1,
wherein at least two of said plurality of horizontally oriented transmission lines are selectively connected to a single receiver circuit.

36. The 3D semiconductor device according to claim 1,
wherein at least two of said plurality of horizontally oriented transmission lines are selectively connected to a single transmitter circuit.

37. The 3D semiconductor device according to claim 1,
wherein said first level comprises at least one Central Processor Unit (“CPU”), and
wherein said first level comprises at least one of:
i. a Graphics Processor Unit (“GPU”), and/or
ii. a Tensor Processor Unit (“TPU”), and/or
iii. a Field Programmable Gate Array (“FPGA”).

38. A 3D semiconductor device, the device comprising:
a first level comprising logic circuits; and
a second level comprising a plurality of memory arrays,
wherein said first level is overlaid by said second level,
wherein said plurality of memory arrays comprise a 3D non-volatile memory array, and
wherein said 3D non-volatile memory array comprises neural network weight parameters.

39. The 3D semiconductor device according to claim 8,
wherein said first level comprises a plurality of multiplier logic circuits.

40. The 3D semiconductor device according to claim 8,
wherein said first level is bonded to said second level, and
wherein said bonded comprises hybrid bonds.

41. The 3D semiconductor device according to claim 8,
wherein said first level comprises at least one Central Processor Unit (“CPU”), and
wherein said first level comprises at least one of:
i. a Graphics Processor Unit (“GPU”), and/or
ii. a Tensor Processor Unit (“TPU”), and/or
iii. a Field Programmable Gate Array (“FPGA”).

42. The 3D semiconductor device according to claim 8, further comprising:
a third level,
wherein said third level comprises a plurality of connectivity units,
wherein said first level is disposed under said third level,
wherein each of said plurality of connectivity units comprises at least one receiver circuit; and
horizontally oriented transmission lines,
wherein at least one of said plurality of connectivity units comprises an Orthogonal Frequency Division Multiple Access (“OFDMA”) modulation circuit.

43. The 3D semiconductor device according to claim 8, further comprising:
a third level,
wherein said third level comprises a plurality of connectivity units,
wherein said first level is disposed under said third level, and
wherein each of said plurality of connectivity units comprises at least one receiver circuit; and
horizontally oriented transmission lines.

44. The 3D semiconductor device according to claim 8, further comprising:
a third level,
wherein said third level comprises a plurality of connectivity units,
wherein said first level is disposed under said third level, and
wherein each of said plurality of connectivity units comprises at least one transmitter circuit; and horizontally oriented transmission lines.

45. A 3D semiconductor device, the device comprising:
a first level comprising logic circuits; and
a second level comprising a plurality of memory arrays,
wherein said first level is overlaid by said second level,
wherein said first level comprises at least one Central Processor Unit (“CPU”), and
wherein said first level comprises at least one of:
i. a Graphics Processor Unit (“GPU”), and/or
ii. a Tensor Processor Unit (“TPU”), and/or
iii. a Field Programmable Gate Array (“FPGA”).

46. The 3D semiconductor device according to claim 15,
wherein said first level comprises a plurality of multiplier logic circuits.

47. The 3D semiconductor device according to claim 15,
wherein said first level is bonded to said second level, and
wherein said bonded comprises hybrid bonds.

48. The 3D semiconductor device according to claim 15, further comprising:
a third level,
wherein said third level comprises a plurality of connectivity units,
wherein said first level is disposed under said third level,
wherein each of said plurality of connectivity units comprises at least one receiver circuit; and
horizontally oriented transmission lines,
wherein at least one of said plurality of connectivity units comprises an Orthogonal Frequency Division Multiple Access (“OFDMA”) modulation circuit.

49. The 3D semiconductor device according to claim 15, further comprising:
a third level,
wherein said third level comprises a plurality of connectivity units,
wherein said first level is disposed under said third level, and
wherein each of said plurality of connectivity units comprises at least one receiver circuit; and
horizontally oriented transmission lines.

50. The 3D semiconductor device according to claim 15, further comprising:
a third level,
wherein said third level comprises a plurality of connectivity units,
wherein said first level is disposed under said third level, and
wherein each of said plurality of connectivity units comprises at least one transmitter circuit; and horizontally oriented transmission lines.
